(19) United States
(12) Patent Application Publication
(10) Pub. No.: US 2010/0139765 A1
(43) Pub. Date: Jun. 10, 2010

(54) SOLAR CONCENTRATORS WITH REMOTE SENSITIZATION

(75) Inventor: Jonathan K. MAPEL, Boston, MA (US)

Correspondence Address: WILMERHALE/BOSTON, 60 STATE STREET, BOSTON, MA, 02109, US

(73) Assignee: COVALENT SOLAR, INC., Cambridge, MA (US)

(21) Appl. No.: 12/627,991

(22) Filed: Nov. 30, 2009

(51) Int. Cl. H01L 31/00

(52) U.S. Cl. 136/257

(57) ABSTRACT

A solar concentrator for concentrating and communicating lower energy light than sunlight to a solar cell, having multiple chromophores physically separated by a sufficient distance for luminescence, and an optical waveguide for directing light to an optical communication region.

### CROSS REFERENCE TO RELATED APPLICATIONS

This application is related to U.S. Provisional Patent Applications Nos. 61/020,946 and 12/363,633, and 61/146,550, the entire contents of which are herein incorporated by reference.

This application is also related to the following applications:

U.S. patent application Ser. No. ______ filed Nov. 30, 2009, entitled “Solar Concentrators with Light Redirection;” and

U.S. patent application Ser. No. ______ filed Nov. 30, 2009, entitled “Solar Concentrators and Materials for Use Therein.”

### BACKGROUND

1. Technical Field of the Invention

Certain embodiments of the technology disclosed herein relate generally to solar concentrators and devices and methods using them. More particularly, certain examples disclosed herein are directed to solar concentrators that use remote sensitization to improve performance.

2. Discussion of Related Art

Photovoltaic (PV) cells may be used to convert solar energy into electrical energy. Many PV cells are inefficient, however, with a small fraction of the incident solar energy actually being converted into a usable current. Also, the high cost of PV cells limits their use as a renewable energy source.

In solar energy transduction systems, the substitution of expensive photovoltaic devices with passive optical elements that redirect light, referred to as concentration, is a method by which the cost per watt of generated power may be reduced. In accordance with one embodiment, a luminescent solar concentrator (LSC) separates the photovoltaic functions of light collection and charge separation. For example, light may be gathered by an inexpensive collector (which may have a relatively large area) comprising a light absorbing material, as discussed below. Light absorbed by the collector may be redirected to a smaller area through guided energy transfer via an optical waveguide. Photovoltaic (PV) cells may be situated over the smaller area to receive the concentrated light. The ratio of the area of the collector to the area of the PV cell is known as the geometric concentration factor, G. One attraction of using a solar concentrator is that the complexity of a large area PV cell may be replaced by a simple optical collector. PV cells are still used, but large G values of a solar concentrator coupled to a PV cell can reduce the PV cost, potentially lowering the overall cost per watt of generated power. It is to be appreciated that although various embodiments of concentrators described below are referred to as “solar concentrators,” they are not limited to receiving and concentrating sunlight only, but instead may be used to concentrate light received from a variety of sources (including, but not limited to, the sun), as discussed further below.

Certain solar concentrators are described in the literature, see, e.g., M. Currie, J. Mapel, T. Heidel, S. Goffri, M. Baldo, Science 321, 226 (2008).

### SUMMARY

The invention provides systems and methods of solar concentration. More specifically, solar concentrators use remote sensitization to improve performance.

Under one aspect of the invention, a solar concentrator for receiving sunlight and for communicating light of lower energy than the sunlight to an optically coupled solar cell, includes a substrate. A primary chromophore operable to receive at least some optical radiation, and is effective to absorb at least one wavelength of at least some of the optical radiation. The primary chromophore is luminescent in a spectral band that is absorbed by the solar cell. An auxiliary chromophore operable to receive at least some optical radiation is effective to absorb at least one wavelength of at least some of the optical radiation. An optical waveguide confines and directs light emitted by the primary chromophore to an optical communication region and includes the substrate and at least one lower refractive index medium adjacent the front and rear surfaces of the substrate, such that light is preferably refracted at an interface between the waveguide and at least one adjacent medium of lower refractive index, wherein the primary chromophore is embedded in the waveguide, is responsive to light within a first spectral band, and emits some light within a second spectral band, wherein the auxiliary chromophore is responsive to light within a third spectral band, and emits at least some light within the first spectral band, and wherein the primary chromophore and the auxiliary chromophore are physically separated by a sufficient distance for the auxiliary chromophore to luminesce.

Aspects and embodiments are directed to systems that employ light guides and luminescent light sources to concentrate light, which can for example be used with photovoltaic devices for the energy conversion of sunlight.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the various aspects and embodiments. Any embodiment disclosed herein may be combined with any other embodiment in any manner consistent with the objects, aims, and needs disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment. Additional features, aspects, examples and embodiments are possible and will be recognized by the person of ordinary skill in the art, given the benefit of this disclosure.

### BRIEF DESCRIPTION OF THE DRAWINGS

In the drawings:

FIG. 1A illustrates an example of a luminescent light guide, according to one embodiment;

FIG. 1B illustrates another example of a luminescent light guide, according to one embodiment;

FIG. 2 illustrates an example of a tandem system of luminescent light guides, according to another embodiment;

FIG. 3 illustrates an example of a system of a luminescent light guide and luminescent light source, according to one embodiment;

FIG. 4A is a graph showing the absorption and emission spectra of a luminescent light guide, in accordance with certain examples;

FIG. 4B is a graph showing the absorption and emission spectra of in a luminescent light source, in accordance with certain examples;

FIG. 4C is a graph showing the absorption and emission spectra of in a luminescent light source, in accordance with certain examples;

FIG. 5 illustrates an example of a system of a luminescent light guide and luminescent light source, according to another embodiment;

FIG. 6 illustrates an example of a system of a luminescent light guide and solar cell, according to another embodiment;

FIG. 7A is a graph showing and example emission pattern of a chromophore plotted in polar coordinates;

FIG. 7B is a graph showing and example emission pattern of a chromophore plotted in x-y coordinates;

FIG. 8A is a legend defining a symbol used in subsequent figures;

FIG. 8B illustrates an example of a system of a solar concentrator and luminescent light source, according to another embodiment;

FIG. 9 illustrates an example of a system of a solar concentrator and luminescent light source, according to another embodiment;

FIG. 10 illustrates an example of a system of a solar concentrator and luminescent light source, according to another embodiment;

FIG. 11 illustrates an example of a system of a solar concentrator, according to another embodiment;

FIG. 12 illustrates an example of a system of a solar concentrator, according to another embodiment;

FIG. 13 illustrates an example of a system of a solar concentrator and a luminescent light sources, according to certain embodiments;

FIG. 14 illustrates an example of a system of a solar concentrator and two luminescent light sources, according to certain embodiments;

FIG. 15 illustrates an example of a system of a solar concentrator and two luminescent light sources, according to certain embodiments;

FIGS. 16A-16C illustrate examples of light redirecting layers for use with solar concentrators, according to certain embodiments;

FIG. 17 illustrates an example of a system of light redirecting layers, a solar concentrator, and PV cells, according to another embodiment;

FIG. 18 shows the increase in optical path length and Fresnel reflection for an example light redirecting layer;

FIG. 19 shows the optical density and luminescence spectra of glasses with selected dopants that may be utilized in luminescent solar concentrators, according to a certain embodiment;

FIG. 20 shows the optical density and luminescence spectra of glasses with selected dopants that may be utilized in luminescent solar concentrators, according to another embodiment;

FIG. 21 shows the optical density and luminescence spectra of glasses with selected dopants that may be utilized in luminescent solar concentrators, according to another embodiment;

FIG. 22 shows the optical density and luminescence spectra of glasses with selected dopants that may be utilized in luminescent solar concentrators, according to another embodiment;

FIG. 23 shows the optical density and luminescence spectra of glasses with selected dopants that may be utilized in luminescent solar concentrators, according to another embodiment;

FIG. 24 shows the optical density and luminescence spectra of glasses with selected dopants that may be utilized in luminescent solar concentrators, according to another embodiment;

FIG. 25 shows the optical density and luminescence spectra of glasses with selected dopants that may be utilized in luminescent solar concentrators, according to another embodiment;

FIG. 26 shows the excitation spectra of glasses with selected dopants that may be utilized in luminescent solar concentrators, according to another embodiment;

FIG. 27 shows the optical density and luminescence spectra of glasses with selected dopants that may be utilized in luminescent solar concentrators, according to another embodiment;

FIG. 28 shows the optical density spectra of glasses with selected dopants that may be utilized in luminescent solar concentrators, according to certain embodiments;

FIG. 29 shows the excitation spectra of glasses with selected dopants that may be utilized in luminescent solar concentrators, according to another embodiment;

### DETAILED DESCRIPTION

Aspects and embodiments are directed to solar concentrators, as well as devices for and methods of using them. Embodiments of solar concentrators disclosed herein may provide significant advantages over existing devices, including higher efficiencies, fewer components, and improved materials and improved optical properties. These and other advantages will be recognized by the person of ordinary skill in the art, given the benefit of this disclosure. Certain examples of the solar concentrators disclosed herein may be used with low cost photovoltaic (PV) cells that comprise amorphous or polycrystalline thin films, as discussed further below.

It is to be appreciated that embodiments of the methods and apparatuses discussed herein are not limited in application to the details of construction and the arrangement of components set forth in the following description or illustrated in the accompanying drawings. The methods and apparatuses discussed herein are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Any references to embodiments or elements or acts of the systems and methods herein referred to in the singular may also embrace embodiments including a plurality of these elements, and any references in plural to any embodiment or element or act herein may also embrace embodiments including only a single element.

It is also to be appreciated that the phraseology and terminology used herein is for the purpose of description and should not be regarded as limiting. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, and upper and lower are intended for convenience of description, not to limit the present systems and methods or their components to any one positional or spatial orientation.

According to one embodiment, the devices and methods disclosed herein are operative to absorb and/or transfer at least some energy. The phrase “at least some” is used herein in certain instances to indicate that not necessarily all of the energy incident on the substrate is absorbed, not necessarily all of the energy is transferred, or not necessarily the energy that is transferred is all emitted as light. Instead, a portion or fraction of the energy may be lost as heat or other non-radiative processes in the solar concentrators disclosed herein.

Certain materials or components are described herein as being disposed on or in another material or component. The term dispose is intended to be interchangeable with the term deposit and includes, but is not limited to, evaporation, co-evaporation, coating, blade coating, mesh coating, screen coating, slot-die coating, spray coating, gravure coating, curtain coating, painting, spraying, brushing, vapor deposition, casting, covalent association, non-covalent association, coordination or otherwise attachment, for at least some time, to a surface.

In solar energy transduction systems, the substitution of expensive photovoltaic devices with passive optical elements that redirect light, referred to as concentration, is a method by which the cost per watt of generated power may be reduced. In accordance with one embodiment, a luminescent solar concentrator (LSC) separates the photovoltaic functions of light collection and charge separation. For example, light may be gathered by an inexpensive collector (which may have a relatively large area) comprising a light absorbing material, as discussed below. Light absorbed by the collector may be redirected to a smaller area through guided energy transfer via an optical waveguide. Photovoltaic (PV) cells may be situated over the smaller area to receive the concentrated light. The ratio of the area of the collector to the area of the PV cell is known as the geometric concentration factor, G. One attraction of using a solar concentrator is that the complexity of a large area PV cell may be replaced by a simple optical collector. PV cells are still used, but large G values of a solar concentrator coupled to a PV cell can reduce the PV cost, potentially lowering the overall cost per watt of generated power. It is to be appreciated that although various embodiments of concentrators described below are referred to as “solar concentrators,” they are not limited to receiving and concentrating sunlight only, but instead may be used to concentrate light received from a variety of sources (including, but not limited to, the sun), as discussed further below.

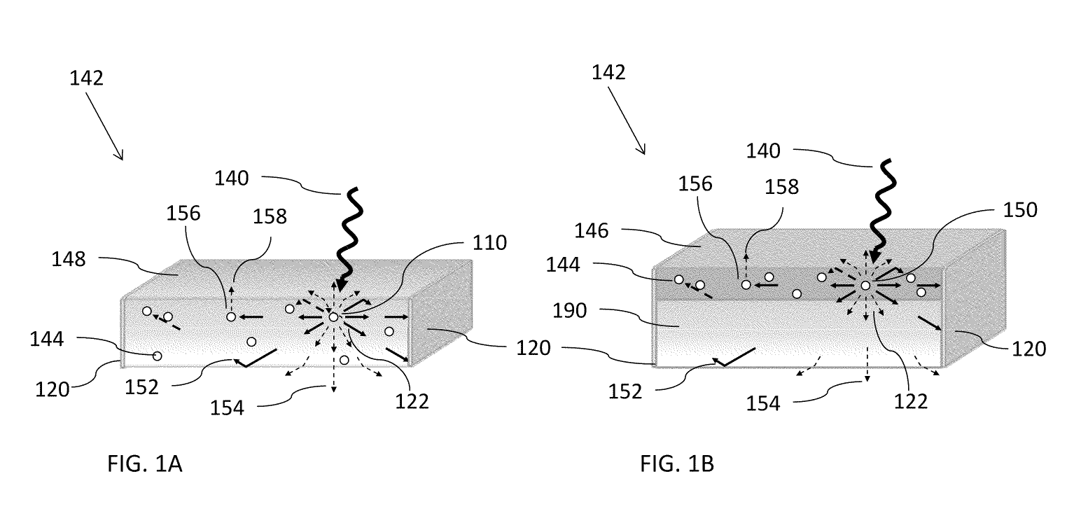

An illustrative schematic of a luminescent solar concentrator (LSC) is shown in FIG. 1A. The LSC 142 comprises a substrate 148 that includes one or more light absorbing materials disposed on or in the substrate 148. A waveguide includes a substrate with a lower refractive index material on at least one surface. The substrate may be rigid or flexible. The substrate 148 is optically coupled to at least one solar cell 120 (also referred to as PV cell) which comprises an area less than the total area of the substrate. Solar radiation 140 is incident on the substrate 148 where it is absorbed by the light absorbing material(s) 144 in the substrate 148. Energy may be re-radiated (see arrows 122) within the substrate 148, and the re-radiated energy may be guided for collection by the PV cells 120, which in this embodiment are attached to the edge faces. One advantage of using LSCs over other optical concentration systems for photovoltiacs such as mirrors, lenses, dishes and the like is that very high concentration factors may be achieved without active cooling or high-accuracy mechanical tracking.

Still referring to FIG. 1A, solar radiation 140 is incident on the substrate 148 where it is absorbed by the chromophores 110 in the substrate 148. The substrate 148 need not be in direct sunlight but instead, may be used to receive direct, indirect and diffuse solar radiation, as discussed further below. An advantage of an LSC having the ability to receive and concentrate diffuse light is that such LSCs do not require solar tracking, which may further reduce system cost. The chromophore 110 can reradiate a photon of equal or lesser energy. Thus, energy from the absorbed solar radiation is re-radiated (as indicated by arrows 122) by the chromophore 110, and some portion of that re-radiated energy will be confined within the substrate 148 by total internal reflection, as indicated by arrow 152. Some portion of the re-radiated energy may also be lost and leave the front or rear faces of the substrate 148, as indicated by the arrow 154. At least some of the trapped re-radiated energy may be guided for collection by the PV cells 120, which are in this embodiment are attached to the edge faces. Some portion of the trapped re-radiated energy may also be re-absorbed by other chromophores 156, which may subsequently by confined, lost through non-radiative processes such as thermalization, or lost through the rear or front face, as indicated by the arrow 158.

The structures of FIGS. 1A and 1B are functionally equivalent but physically different in that 1B, the chromophores reside in a higher concentration in a subregion of the optical element. This is embodiment, the chromophores 150 may be coated into a thin film 146 onto a transparent substrate 190.

The chromophores absorb incident, ambient light, which may be sunlight 140. The chromophores are chosen to have non-zero photoluminescence efficiency, whereupon they have a finite probability of re-emitting light of a lower energy than that which they absorbed.

The refractive index of the optical element is greater than that of its surrounding media, such that total internal reflection is possible. A chromophore that has absorbed incident light may emit light that is confined within the optical element by total internal reflection (152), or which exits directly (154). The direction and polarization of the emitted light determines whether it will be confined or lost.

In certain embodiments, one or more of the chromophores can be a material that is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, pyradines, indocyanine green, styryls (Lambdachrome series), dioxazines, naphthalimides, thiazines, stilbenes, IR132, IR144, IR140, Dayglo Sky Blue (D-286), Columbia Blue (D-298), quantum dots or otherwise nanostructured chromophores (such as indium phosphide, indium arsenide, copper indium selenide, lead sulfide, lead selenide, a group II/IV semiconductor heterostructure, a group III/V semiconductor heterostructure, and a cadmium selenide/cadmium sulfide heterostructure), rare earth metal ions (such as europium, neodymium, chromium, and uranium), rare earth metal ion doped glass microspheres and nanospheres, and organometallic complexes of rare earth metals (such as europium, neodymium, chromium, and uranium, such as, for example, those described in C. Adachi, M. A. Baldo, S. R. Forrest, Journal of Applied Physics 87, 8049 (2000); K. Kuriki, Y. Koike, Y. Okamoto, Chemical Reviews 102, 2347 (2002); H. S. Wang, et al, Thin Solid Films 479, 216 (2005); Y. X. Ye, et al, Acta Physica Sinica 55, 6424 (2006); J. S. Batchelder, A. H. Zewail, T. Cole, Applied Optics 20, 3733 (1979). These examples are illustrative and not restrictive. Other materials are also envisioned and may be used.

Illustrative materials for use in the substrates of the solar concentrators disclosed herein include, but are not limited to, polymethylmethyacrylate (PMMA), glass, lead-doped glass, lead-doped plastics, aluminum oxide, polycarbonate, polyamide, polyester, polysiloxan, polyester resins, epoxy resins, ethyl cellulose, polyethylene terephthalate, polyethylenimine, polypropylene, poly vinyl chloride, soda lime glass, borosilicate glasses, acrylic glass, aluminum oxynitride, fused silica, halide-chalcogenide glasses, titania-doped glass, titania-doped plastics, zirconia-doped glass, zirconia-doped plastics, alkaline metal oxide-doped glass, alkaline metal oxide-doped plastics, barium oxide-doped glass, barium-doped plastics, cellulosic esters, polystyrene, nylons, zinc oxide-doped glass, and zinc oxide-doped plastics. In certain examples, the dimensions of the substrate may vary depending on the desired efficiency, overall size of the concentrator and the like. In particular, the substrate may be thick enough such that a sufficient amount of light may be trapped, e.g., 70-80% or more of the quanta of radiation (i.e., 70-80% of the incident photons). In certain examples, the thickness of the substrate may vary from about 1 mm to about 12 mm, e.g., about 1.5 mm to about 10 mm. The overall length and width of the substrate may vary depending on its intended use, and in certain examples, the substrate may be about 10 cm to about 300 cm wide by about 10 cm to about 300 cm long. The exact shape of the substrate may also vary depending on its intended use environment. In some examples, the substrate may be planar or generally planar, whereas in other examples, the substrate may be non-planar. In certain examples, opposite surfaces of the substrate may be substantially parallel, whereas in other examples opposite surfaces may be diverging or converging. For example, the top and bottom surfaces may each be sloped such that the width of the substrate at one end is less than the width of the substrate at an opposite end.

Illustrative materials for use in the PV cells that receive the confined luminescence disclosed herein include, but are not limited to, cadmium telluride, cadmium indium gallium selenide, copper indium sulfide, amorphous silicon, monocrystalline silicon, multicrystalline silicon, amorphous-silicon/muticrystalline-silicon micromorph, cadmium selenide, aluminum antimonide, indium phosphide, indium gallium phosphide, aluminum arsenide, gallium phosphide, gallium antimonide, dye-sensitized solar cells utilizing, for example, ruthenium dyes, or organic solar cells utilizing, for instance, fullerene, poly(3-hexylthiophene), and phenyl-C61-butyric acid methyl ester, such as, for example, those described in A. Luque, S. Hegedus eds. Handbook of Photovoltaic Science and Engineering, John Wiley, Chichester (2003); A. Luque, V. Andreev eds. Concentrator Photovoltaics, Springer-Verlag Berlin (2007). These examples are illustrative and not restrictive. Other materials are also envisioned and may be used.

In accordance with certain examples, the chromophores used in the concentrators disclosed herein may be disposed using numerous different methods including, but not limited to, painting, brushing, spin coating, casting, molding, drop casting, spraying, dip coating, blade coating, slot die coating, mesh coating, sputtering, vapor deposition (e.g., physical vapor deposition, chemical vapor deposition and the like), plasma enhanced vapor deposition, pulsed laser deposition and the like. In some examples, organic vapor phase deposition (OVPD) may be used to deposit at least one of the components of the solar concentrators disclosed herein. OVPD may be used, for example, to dispose or coat a waveguide with one or more chromophores, red-shifting agents, heavy metals or the like. In some examples, OVPD may be used to produce a solar concentrator by disposing a vapor phase of the chromophore on a substrate and optionally curing or heating the substrate. Illustrative devices for OVPD are commercially available, for example, from Aixtron (Germany). Suitable methods, parameters and devices for OVPD are described, for example in Baldo et al., Appl. Phys. Lett. 71(2), 3033-3035, 1997.

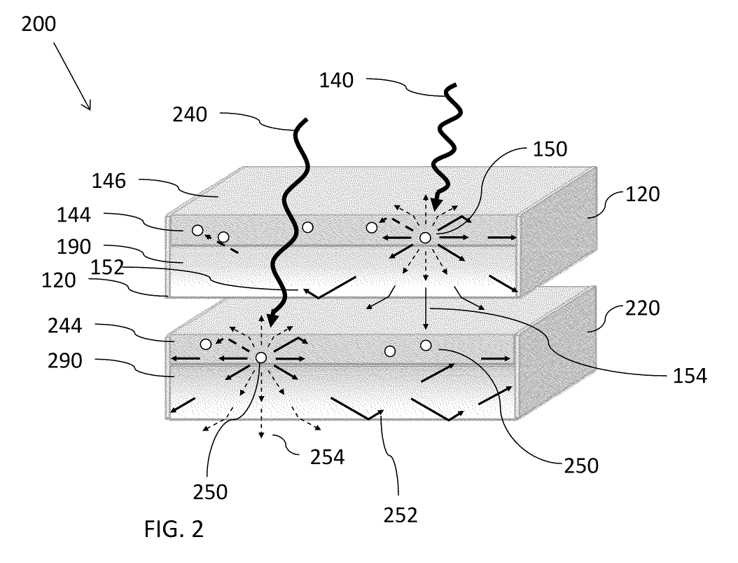

According to one embodiment, two or more PV cells with different electrical bandgaps may be used, such that one of the PV cells absorbs light within a first wavelength range and at least one of the other PV cells absorbs light within a second wavelength range different from the first wavelength range. For example, referring to FIG. 2, LSC 246 may be designed to operate with the first PV cell 120 being a high bandgap PV cell and the second PV cell 220 being a low bandgap PV cell. Thus, certain light wavelengths 140 may be absorbed by the chromophore 150 and re-emitted for absorption by the first PV cell 120, while other light wavelengths 240 are transmitted through the LSC 146 and absorbed by a second LSC. Converting light to electrical current with multiple electrical bandgaps in a tandem configuration, such as illustrated in FIG. 2, allows a higher fraction of the light's optical power to be converted to electrical power. Furthermore, in an optical system, (such as optical system 200) comprised of a top system comprised of a concentrator 146 collecting light to be converted at a high bandgap PV cell 120 and a bottom system comprised of a lower electrical bandgap PV cell 220 attached to a different LSC, the requirements of current density matching are alleviated as the two systems no longer need to be connected serially. A device that satisfies these designs is described in M. Currie, J. Mapel, T. Heidel, S. Goffri, M. Baldo, Science 321, 226 (2008).

In accordance with another embodiment, two or more waveguides may be optically coupled such that one of the waveguides absorbs light within a first wavelength range and at least one of the other waveguides absorbs light within a second wavelength range different from the first wavelength range. Devices that include two or more waveguides are referred to in certain instances herein as tandem devices. The tandem device may include two solar concentrators as described herein and as discussed above with reference to FIG. 2.

In one embodiment, a tandem luminescent solar concentrator (LSC) is produced by stacking two or more waveguides onto each other or otherwise optically coupling two or more waveguides. Referring again to FIG. 2, one example of a tandem luminescent solar concentrator 200 comprises a first waveguide 190 disposed or stacked on a second waveguide 290. According to one embodiment, the waveguides 190, 290 may be attached or otherwise coupled to one or more PV cells 120, 220 with selected bandgaps so a greater fraction of each photon's power will be extracted. For example, the top waveguide 190 may be configured to concentrate visible radiation on a first PV cell 120 coupled to the waveguide 190. PV cell 120 may be, for example, a gallium indium phosphide (GaInP) or gallium arsenide (GaAs) PV cell. The bottom waveguide 290 may be configured to concentrate a different wavelength range of radiation on a second PV cell 220 coupled to the waveguide 290. In one example, the second PV cell 220 may be a GaAs or silicon PV cell. In another example, the bottom waveguide 290 includes a chromophore 260 that is disposed into thin film coating 244 configured to absorb radiation with wavelengths greater than 650 nm and provide such radiation to the second PV cell 220. The second PV cell 220 may be, for example, a silicon PV cell.

Still referring to FIG. 2, solar radiation 240 is incident on the lower substrate 290 where it is absorbed by the chromophores 250 in or on the substrate 290. In addition, light may be incident upon the substrate 290 that originated from re-radiation of a chromophore disposed in the substrate 190 that has been emitted through the rear face (154). The chromophore 250 can reradiate a photon of equal or lesser energy. Thus, energy from the absorbed solar radiation is re-radiated by the chromophore 250, and some portion of that re-radiated energy will be confined within the substrate 290 by total internal reflection, as indicated by arrow 252. Some portion of the re-radiated energy may also be lost and leave the front or rear faces of the substrate 290, as indicated by the arrow 254. At least some of the trapped re-radiated energy may be guided for collection by the PV cells 220, which in this embodiment are attached to the edge faces. Some portion of the trapped re-radiated energy may also be re-absorbed by other chromophores, which may subsequently by trapped, lost through non-emission, or lost through the front or rear face.

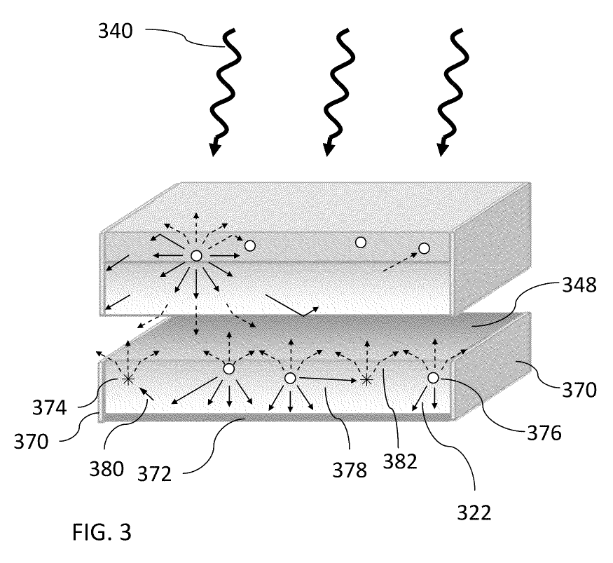

In one embodiment, a system is formed whereupon an LSC receives direct illumination and a second optical element that functions as a luminescent light source receives light transmitted through the LSC and redirects light at longer wavelengths towards the LSC. For example and referring to FIG. 3, chromophores 376 may be disposed in a substrate 348. Following absorption of light 340 transmitted through an LSC, the chromophore 376 can reradiate a photon of equal or lesser energy. Thus, energy from the absorbed solar radiation is re-radiated (as indicated by arrows 322) by the chromophore 376. The substrate preferentially contains additional scattering centers 374. Some portion of the re-radiated light may reach 378 a scattering center 374, whereupon its direction will change. Some portion of the re-directed light may leave the luminescent light source directly (382). Some portion of the re-radiated light may travel to the rear or edge faces of the luminescent light source, where one or more reflective surfaces 370 and 372 reside. Such light will be reflectively redirected (380), where it may be further re-directed by the scattering centers 374. The scattering centers 374 are distributed within or on the luminescent light source such that light will be intercepted by a scattering center before traveling a significant distance in the substrate 322. Unlike the LSC, the luminescent light source is designed to redirect light toward the LSC as opposed to collecting and concentrating light to a smaller area for conversion by PV cells. No optical to electrical energy conversion occurs at the luminescent light source.

The chromophores may additionally serve as scattering centers, although they are principally included as materials to absorb light transmitted through the LSC. The concentration of chromophores and scattering centers need not be identical. The concentration of chromophores may be chosen such that substantially all of the light incident upon them is absorbed over the spectral range of which they are optically active. The concentration of scattering centers may be chosen such that the luminescent light intensity is substantially uniform along its emissive face. The reflective surfaces are included to increase the brightness of the luminescent light source.

In accordance with certain examples, the scattering centers used in the luminescent light sources disclosed herein may be disposed using numerous different methods including, but not limited to, mechanical means, such as scratching, abrasion, chemical etching, or rubbing, as well as chemical means, such as the disposition of scattering materials, such as crystalline regions, transparent nanoparticles, colloids, oxides, ions, paints, or pigments. The scattering centers may be distributed throughout the bulk of the substrate supporting the luminescent light source, or may be concentrated in a coating within the interior of or on the front or rear surface of the luminescent light source. The coating may be directly applied onto a supporting substrate or the scattering centers may reside in a self-supporting film which may be laminated to the luminescent light source.

Illustrative materials for use in the substrates of the luminescent light sources disclosed herein include, but are not limited to, polymethylmethyacrylate (PMMA), glass, lead-doped glass, lead-doped plastics, aluminum oxide, polycarbonate, polyamide, polyester, polysiloxan, polyester resins, epoxy resins, ethyl cellulose, polyethylene terephthalate, polyethylenimine, polypropylene, poly vinyl chloride, soda lime glass, borosilicate glasses, acrylic glass, aluminum oxynitride, fused silica, halide-chalcogenide glasses, titania-doped glass, titania-doped plastics, zirconia-doped glass, zirconia-doped plastics, alkaline metal oxide-doped glass, alkaline metal oxide-doped plastics, barium oxide-doped glass, barium-doped plastics, cellulosic esters, polystyrene, nylons, zinc oxide-doped glass, and zinc oxide-doped plastics. In certain examples, the dimensions of the substrate may vary depending on the desired efficiency, overall size of the concentrator and the like.

In some instances, the reflective surfaces may be directly attached to the luminescent light source, while in others, the reflective surface may be separated from the luminescent light source by a gap filled with air or other gases. The reflective surfaces may be of any type that may function to reflect light, include mirrors made of metal or dielectrics, multilayer dielectric stacks, or diffuse reflectors formed from rough, white pigments or oxides.

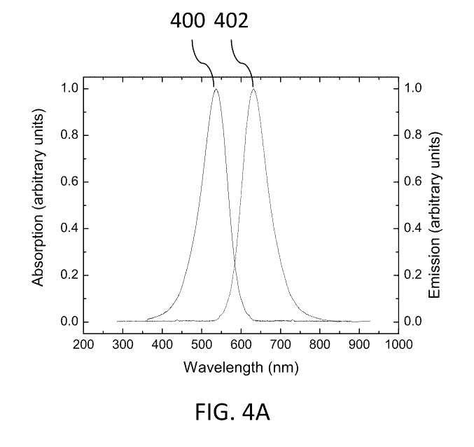

The inclusion of a luminescent light source may be desirable compared to a single LSC guide or a tandem stack of LSCs in that the optical constraints on the chromophores may be relaxed. Referring to FIG. 1, the processes by which re-radiated light is re-absorbed by another chromophore 156 and potentially lost through thermalization or emission out of an LSC face (158) is desirably minimized. This constraint encourages the inclusion of chromophores which are maximally transparent to their own emitted light. In general, not all chromophores satisfy this criterion. For example and referring to FIG. 4A, the degree to which self-transparency can be quantified is the spectral overlap between absorption and emission. The example absorption spectrum (400) of a chromophore is plotted with an example emission spectrum of the same chromophore (402). Photons are emitted with a probability weighted by the emission spectrum, and those emitted with wavelength in the region of spectral overlap (in this example, around 600 nm), have a substantial probability of being re-absorbed.

Various methods to overcome this constraint for the inclusion of chromophores in LSCs are described in U.S. Provisional Patent Application No. 61/020,946. Several of the methods include the use of near field energy transfer mediated by Förster processes. Energy transfer enables the separation of light absorption and light emission into chemically distinct chromophores. Emission occurs at the chromophore with longest wavelength (lowest energy) emission spectrum.

In general, one or more chemically distinct chromophore species may be utilized in an LSC. For example and referring to FIG. 4B, the absorption spectra of two types of chromophores are plotted (404 and 406). The lower energy emitter with absorption spectrum 406 has an emission spectrum 408. The absorption spectra of an LSC that contains various chromophores may, in general, have regions of low absorption strength. In FIG. 4B for example, the absorption strength decreases for wavelengths<450 nm. In general, this condition may be remedied by the inclusion of additional chromophores. However, the net efficiency of light concentration may be reduced if the energy transfer efficiency is low, or the likelihood of re-absorption increases.

Additionally, the inclusion of chromophores to increase light absorption may not transfer energy with high efficiency to the lowest energy emitter if, for instance, the inter-chromophore distance is long. This is the case if, for instance, one chromophore is disposed within the LSC and another chromophore is disposed into a coating onto the LSC. Chromophores physically located at distances greater than 100 nm will not transfer energy with high efficiency, and light quanta may lost, lowering the number of photons reaching the PV cell and undesirably lowering LSC power output.

In accordance with another example, a single chromophore species may be utilized in an LSC which may possess spectral regions of low absorption strength. In general, this condition may be remedied by the inclusion of additional chromophores. However, the net efficiency of light concentration may be reduced if the energy transfer efficiency is low, or the likelihood of re-absorption increases.

The inclusion of a luminescent light source at the rear of the LSC is a general method to increase the absorption efficiency in an LSC where direct addition of chromophores may undesirably reduce system power output. The luminescent light source should be desirably designed to have high absorption and emission efficiency, but the requirement of low re-absorption probability, or high emitting-chromophore self-transparency, is removed.

To maximize total system power output, the system should be designed according to several rules. The LSC should be designed with a one or more chromophore species that possess(es) high emitting-chromophore self-transparency and high LSC light-absorption efficiency. However, the high light absorption efficiency need only exist over a narrow spectral range. The luminescent light source should be designed to have high absorption efficiency over the wavelength range where absorption in the LSC in incomplete, especially for wavelengths shorter than the range where light absorption is high. The emission spectrum of the one or more chromophore mixture in the luminescent light source should overlap with the spectral range where absorption efficiency in the LSC is high.

In accordance with particular embodiment, FIG. 4B illustrates the optical properties of two chromophores that when used together, may be used in an LSC that possesses optical properties that may result in high power output when in concert with a luminescent light source. FIG. 4C illustrates the absorption spectrum (410, 412) of three chromophores and the emission spectrum (414) of the chromophore that emits light of the lowest energy of the chromophores that when used together, may be used in an luminescent light source that possesses optical properties that may result in high power output when used in concert with an LSC. In general, the number of chromophore species in each of the LSC and luminescent light source may be chosen such that system power output is maximized by satisfying the above-listed design criteria for spectral performance.

Practical deployment of PV modules requires stringent performance lifetimes to reduce the lifetime levelized cost of generated electricity. Degradation in PV module performance efficiency and failure is precipitated by exposure to heat, oxygen, water, and high-energy radiation, and commercially available modules are designed to keep out these elements. High energy radiation is a particularly damaging degradation cause, as it catalyzes destructive reactions with heat, oxygen, and water.

In the embodiment illustrated in FIG. 3, UV light may be collected and concentrated in the LSC before reaching the components below, including the luminescent light source. By not transmitting high energy radiation like ultraviolet (UV) light to the luminescent light source, materials with less robust photostability can be utilized. A module design that incorporates an LSC that collects UV light does not require specialized coatings that either reflect or passively absorb UV light, which increase cost and reduce absorption efficiency.

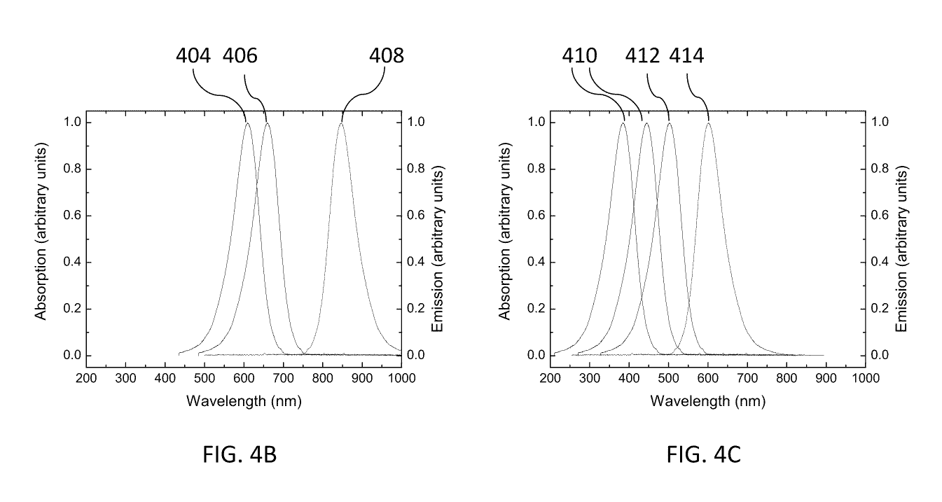

In an alternate embodiment, a solar concentrator is formed whereupon an LSC received direct illumination and a second optical element that functions as a luminescent light source receives light transmitted through the LSC and redirect it back towards the LSC. For example and referring to FIG. 5, chromophores 576 may be disposed on a substrate 596. Following absorption of light 540 transmitted through an LSC, the chromophore 576 can reradiate a photon of equal or lesser energy. Thus, energy from the absorbed solar radiation is re-radiated (as indicated by arrows 578) by the chromophore 576. The substrate preferentially contains additional scattering centers 574. Some portion of the re-radiated light 578 may reach a scattering center 574, whereupon its direction will change. Some portion of the re-directed light may leave the luminescent light source directly (582). Some portion of the re-radiated light may travel to the rear or edge faces of the luminescent light source, where one or more reflective surfaces 570 and 572 reside. Such light will be reflectively redirected (580), where it may be further re-directed by the scattering centers 374. The scattering centers 574 are distributed within or on the luminescent light source such that light will be intercepted by a scattering center before traveling a significant distance in the substrate 596. Unlike the LSC, the luminescent light source is designed to redirect light toward the LSC as opposed to collecting and concentrating light to a smaller area for conversion by PV cells.

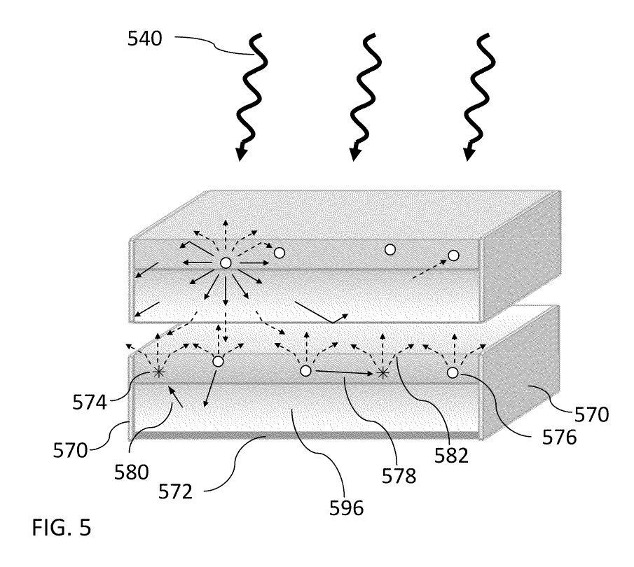

In one embodiment, a system is formed whereupon an LSC receives direct illumination and a second optical element that functions as a luminescent light source receives light transmitted through the LSC. The luminescent light source redirects light at longer wavelengths towards the LSC and a PV cell situated beneath the luminescent light source. For example and referring to FIG. 6, the luminescent light source is formed from chromophores 676 disposed of on a film that resides adjacent to a PV cell 692 which resides on top of and is supported by a substrate 690. Unlike the LSC, the luminescent light source is designed to redirect light up towards the LSC and down towards the PV cell, as opposed to collecting and concentrating light to a smaller area of PV cells. Reflective surfaces 670 may be optionally attached at the edge faces of the luminescent light source.

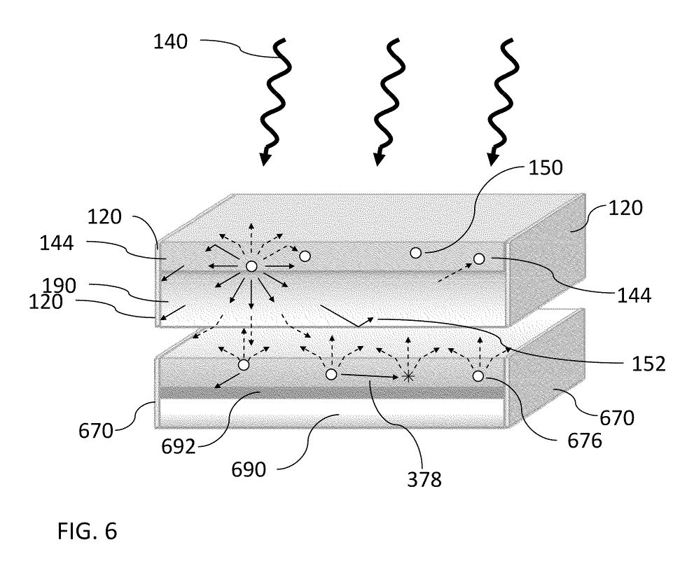

In one embodiment, the physical orientation of the chromophores may be controlled to increase the number of photons that are confined in the LSC. Referring to FIG. 7A and FIG. 7B, the emission intensity of a dipole antenna is plotted. The emission pattern of a single chromophore closely approximates the sin² θ radiation pattern of a dipole antenna, where θ represents the angle between the dipole axis and the direction of emission. In FIG. 7A, the dipole axis coincides with 90° and 270°, which is also the vertical axis line. The directions of maximum emission intensity are perpendicular to the dipole axis, which is also the horizontal axis line, which is the axis that coincides with 0° and 180°. FIG. 7B plots the same emission direction intensity pattern on x-y axes.

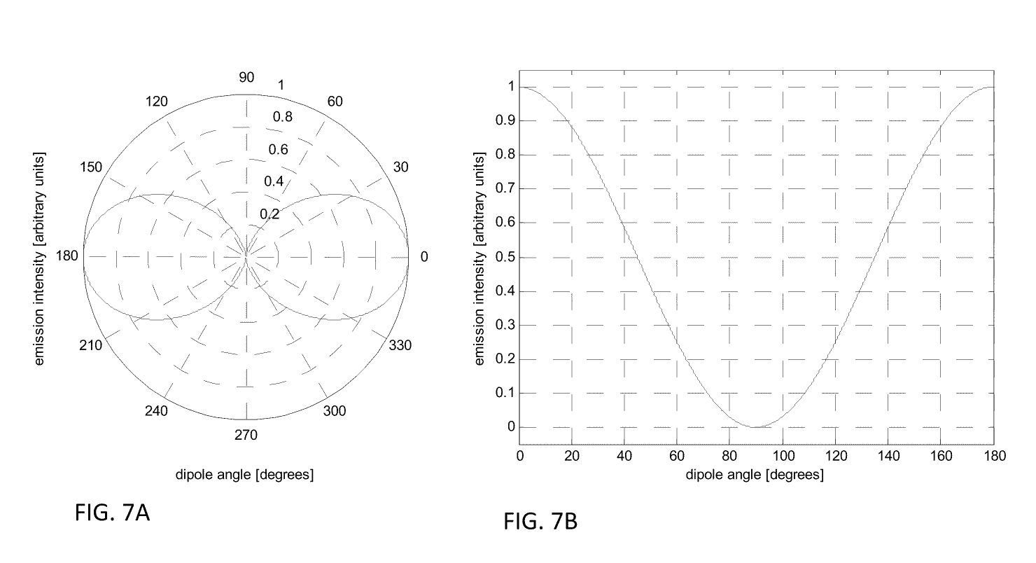

Referring to FIG. 8A, a compact notation is introduced to facilitate explanation in future figures. The dipole axis 802 is represented by a solid arrow. The solid circle 808 represents the location of the chromophore. The black curve 804 represents the emission direction intensity pattern, where the distance between the line and the center of the circle represents the relative emission intensity for that radial direction. The dotted lines 806 point towards the directions of maximum emission intensity, which is perpendicular to the dipole axis 802.

In one embodiment, a system 800 is formed whereupon an LSC receives direct illumination and a second optical element that functions as a luminescent light source receives light transmitted through the LSC and redirect light at longer wavelengths towards the LSC. For example and referring to FIG. 8B, chromophores 846 may be disposed in or on a substrate 890, forming a luminescent light source. Following absorption of light 240 transmitted through an LSC, the chromophore 846 can reradiate a photon of equal or lesser energy. Thus, energy from the absorbed solar radiation is re-radiated by the chromophore 846. The chromophores 846 are physically oriented such that the emitted light is preferentially directed towards the direction perpendicular to the flat entrance face of the luminescent light source. Light confinement is the luminescent light source is desirably minimized. Photons that approach the front surface of the luminescent light source and encounter a change in media will be redirected according to the change in the index of refraction and initial direction according to Snell's Law. By physically orienting the chromophore dipole axis to be parallel to the front entrance face of the luminescent light source, a large fraction of the emitted light will be directed perpendicular to the front entrance face of the luminescent light source, and exit the luminescent light source in a trajectory bound for the LSC. An optional reflective surface 872 may be attached to the opposing face of the luminescent light source, which functions to increase the intensity of light redirected towards the LSC.

The chromophores in the luminescent light source are desirably oriented with dipole axes parallel to the front surface face of the luminescent light source. Exact parallel orientation is not necessary, and an increase in system power output may be achieve with orientation within an angular range. Illustrative dipole orientation may include, but are not limited to, between 0° and 30° from parallel, more particularly 0° to 25°, for example, about 0° to 20°.

The chromophores 844 disposed in or on the LSC are not controllably oriented and the dipole axes are randomly oriented, resulting in a far-field isotropic emission pattern.

In certain examples, chromophore emission direction may be controlled through physical alignment of light emitting species in either the LSC or luminescent light source. For example, each emission species has a radiation pattern dependent on the spatial structure of its electronic energy levels. The physical orientation of the emitter is linked to its radiation pattern. By controlling physical orientations, direct control of confinement efficiency and/or emission direction can be achieved.

In one embodiment, physical orientation may be controlled by trapping the chromophore in a matrix such that free rotation is limited and the chromophore molecules are oriented in a selected plane or direction. For example, where the chromophores used have a charge or a dipole moment, an electric field may be used to align the chromophores and keep the chromophores oriented in a certain direction. The electric field may be maintained during operation or, as discussed below, may be removed subsequent to one or more processing steps.

In certain examples, after alignment of the chromophores with the electric field, the matrix surrounding the chromophores may be polymerized or cross-linked to trap the chromophores in the oriented direction. If the overall size of the chromophores are about the same size or slightly smaller, e.g., 5-10% smaller, than the overall size of the void space where the chromophore resides, then free rotation may be limited and the general direction of the chromophore can be retained even after the electric field is removed.

In some examples, the chromophore may be added to a pre-polymerized matrix in a desired amount. In certain examples, it is desirable that the matrix be saturated with the chromophore such that the overall absorption and/or emission efficiency of the LSC or the luminescent light source can be increased. In certain examples, after polymerization of the matrix, a terminal chromophore can be coated onto the matrix such that light energy absorbed by the tuned chromophore molecules of the matrix can be transferred to the terminal chromophore. In other examples, the pre-polymerized matrix/chromophore mixture may be coated onto a substrate that includes an absorbing chromophore. Subsequent to coating, the mixture can be polymerized to provide a tuned terminal chromophore which can function to receive energy from the absorbing chromophore. To increase the overall efficiency of the LSC, it may be particularly desirable to use two or more different chromophores to separate the absorption and emission functions of the LSC.

In some examples, two or more chromophores may be added to the pre-polymerized matrix. For example, one of the chromophores may function to absorb light energy and the other may function to emit light energy. In certain embodiments, as discussed below, it may be desirable to orient the absorbing chromophore perpendicular to the incident light rays and/or parallel to the guiding direction. The absorbing chromophore can transfer energy to the emitting chromophore which can emit light in a selected direction. As discussed further below, the LSC can be oriented at a selected angle with respect to a PV cell to provide light to the PV cell.

In some examples, the polymer matrix may be a single type of material or may be a mixture of two or more materials. Where a single monomer is present in the polymer, e.g., a homopolymer, the monomer may be styrene, butadiene, ethylene, propylene, glucose or other suitable monomers. Illustrative homopolymers include polystyrene, polybutadiene, polyethylene, cellulose, polyarylenes, polyacrylates polymethacrylates and the like. In examples where a copolymer is present, the copolymer may be, for example, an AB diblock, an ABA triblock, an ABC triblock, or a starblock copolymer. Specific types of copolymers include, but are not limited to, styrene-butadiene-styrene (SBS), styrene-ethylene-butylene (SEBS), styrene-ethylene-propylene (SEPS) and other block copolymers including two or more different monomers.

In certain embodiments, the polymer may be polymerized by exposing it to increased temperature, ultraviolet light, one or more initiators or other conditions or materials that can cross-link or polymerize the monomers of the polymer. For example, a chromophore may be mixed with liquid polymer, an electric field may be applied, and then heat may be applied to cross-link the polymer and trap the chromophore in a certain orientation. In other examples, a chromophore may be mixed with liquid polymer, an electric field may be applied, and then the mixture may be exposed to ultraviolet light to cross-link the polymer and trap the chromophore in a certain orientation.

While alignment is described above using an electric field, other stimulus and perturbations may be used to orient the chromophores. For example, a magnetic field, charged species in the matrix, matrix ligands, etc. may be used to force the chromophore to align in a certain direction in the matrix. Such alignment may occur, for example, as the chromophore interacts through chemical and/or physical interactions with the matrix. In some examples, one or more charged groups of the matrix may chemically bond to the chromophore to constrain free rotation of the chromophore and orient the chromophore within the matrix. For example, the matrix may include internal ligands that comprise one or more functional groups capable of reacting with the chromophore. Illustrative functional groups include, but are not limited to, a siloxane, an amine, a phosphine, a phosphine oxide, a phosphonate, a phosphonite, a phosphonic acid, a phosphinic acid, a thiol, an alcohol, a hydroxyl group, a phenylhydroxy group and the like. In other examples, the matrix may include aromatic or heteroaromatic structures such that interaction of the pi system of a chromophore with the pi system of the aromatic can orient the chromophore. For example, stacking of aromatic structures, through pi-pi interactions, may occur within the matrix to align the chromophore molecules in a certain direction.

In certain embodiments, the emitting chromophore can be placed or added to a local environment to constrain its physical orientation. The local environment, or matrix, can be patterned or stretched to achieve anisotropy in its physical properties. In addition, the molecular structure of the matrix can be directly designed to favor a physical anisotropy as with block copolymers. The emitters can reside in this matrix and be sterically hindered to adopt a specific conformation to reduce its energetic interaction with the matrix.

As discussed above, some emitters possess a strong electronic dipole which can interact with local electronic fields. If the dipoles exist within a liquid or viscous medium, they can rotate or align to the electric field, lowering their free energy. This is the physical mechanism affecting operation of liquid crystal displays (LCDs). For both LCD's, LSC's, and luminescent light sources, the optical transmission properties of the aligned dipoles can be controlled. Dipole alignment to an electric field can be utilized during the manufacturing process of LSC's or luminescent light sources, after which the position can be frozen through various methods, including light or heat induced polymerization of the matrix material. In some examples, liquid crystals may be doped into the matrix such that alignment of the liquid crystal in the electric field also results in alignment of the chromophore within the electric field. Where the chromophore molecule is anisotropic, different optical properties may be provided versus the use of an isotropic chromophore. The tuned chromophores described herein may be isotropic, anisotropic or include a mixture of isotropic and anisotropic species to provide desired optical properties. Similarly, isotropic and anisotropic liquid crystals may be used to alter the optical properties of the LSC or luminescent light sources as desired.

In certain embodiments, for LSC's or luminescent light sources that are formed of an emissive material on a substrate, the emitters can be aligned to the interface between the coating and substrate through direct self assembly. For instance, the emitters can covalently bind to the substrate and pack densely to maximize interface linkage. Depending on emitter physical structure, dense packing can result in physical alignment. For instance, the linear physical structure of alkanethiols and octedecyltrichlorosilanes result in self assembly of monolayers on metallic and oxide substrate, respectively. These layers can be deposited sequentially, retaining alignment throughout. The overall distribution of the self-assemblies can vary, and in certain examples, there may be a substantially uniform distribution of species along the surface of the device. In other examples, the substrate can be masked prior to addition of the chromophores such that only certain regions of domains include the self-assembled chromophores. In some examples, regions may be etched away to remove self-assembled chromophores in certain areas.

In certain embodiments, the terminal chromophore can be oriented within a supramolecular aggregate where only a portion of the aggregate emits light and the rest of the aggregate functions as an antenna to funnel absorbed light to the emitter. These aggregates can be linked by chemical bonds, constraining the orientation of emitters relative to the rest of the aggregate. Alternatively, these aggregates can be linked by physical interactions with each other to form a complex or assembly of components that have different functions in the overall assembly. For example, one component of the complex may function to absorb incident light and another component of the complex may function to emit the light, e.g., function as a terminal chromophore. Illustrative aggregates and complexes are described, for example, in U.S. Provisional Patent Applications No. 61/146,550, the entire disclosure of which is hereby incorporated herein by reference for all purposes.

In certain examples, the physical alignment emitters in an operational LSC or luminescent light source can fall within a restricted angular range if, during fabrication, a subset of emitters can be deactivated. For instance, if a fabrication method is used that results in an isotropic emitter pattern, a subset can be turned off, resulting in narrower angular range of emitters. This deactivation can be controlled if the emitters exhibit an anisotropic interaction with some deactivating force. For instance, this could be absorption and oxidation followed by absorption of high energy electromagnetic radiation or a particle stream. The anisotropic interaction could be due to polarization or directionality of incoming radiation. The interaction may be due to the presence of an additive in the device that results in deactivation of certain chromophore molecules. For example, a quencher can be added to certain areas of the LSC luminescent light source such that chromophores near the quencher do not substantially emit light. In some examples, the deactivator or deactivating force may be constructed and arranged to provide a desired emission pattern. For example, the device may be constructed such that only a small slit or linear portion of the device emits light whereas other portions are designed to absorb incident light but do not substantially emit. Such configuration permits coupling of a PV cell to the LSC or luminescent light source at a specific region to provide emitted light at a specific angle.

In certain embodiments, for LSCs or luminescent light sources that are formed of a coating of an emissive material on a waveguide substrate, the physical orientation can be controlled if the emitter resides in a viscous medium that is extruded through a small opening. For instance, die heads in roll coaters can include very small fluid output slits. During fluid travel through these slits, materials (both emitters and the matrix) can align to the travel direction and be coated in an anisotropic manner. After coating solidification, the anisotropy can be retained, triggered by thermal or photo treatments.

In other examples, the chromophore may be placed in a material that can undergo a transition with temperature. For example, at high temperatures the material may undergo a transition to become more viscous or less viscous. Similarly, materials may be selected that become more or less viscous as temperature is decreased. Illustrative materials include, but are not limited to, sols, gels, hydrogels and the like. Where such materials are present, the LSC may include a layer of the material encapsulated by two or more surfaces to prevent loss of the material. For example, a small amount of the material may be inserted between glass plates, e.g., high refractive index glass plates, and the glass plates can be sealed to prevent loss of the material. The temperature may be controlled through the use of active heating or cooling elements or the material may be selected based on the intended use temperature to provide a desired viscosity at the use temperature. Illustrative viscosities that may be present include, but are not limited to, about 1 cP to about 5000 cP, more particularly about 10 cP to about 500 cPs, for example, about 75 cP. In addition, where the viscosity is too low or too high, one or more thixotropic agents may be added to alter the viscosity to a desired value or range.

In some examples, the viscous medium may be used to hold or retain the orientation of the chromophores for such a time until the chromophore can be fixed by other means, e.g., cross-linking of the matrix. In such embodiments, the viscous medium may subsequently be removed to avoid any unnecessary optical effects that may be produced from the presence of the viscous medium. Such removal may be accomplished by washing, evaporation or other suitable processes. In certain examples, the viscous medium can participate in cross-linking of the matrix such that the resulting polymer is a combination of monomer matrix species and the components of the viscous medium. Other uses of a viscous medium to align the chromophores will be selected by the person of ordinary skill in the art, given the benefit of this disclosure.

The chromophores disposed in or on the LSC and luminescent light source may be chosen to satisfy the design criteria espoused in the description of FIG. 4.

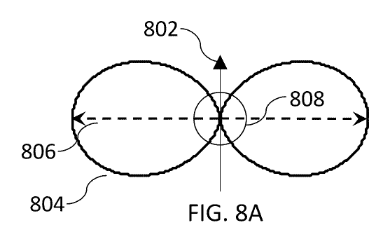

In one embodiment, a system 900 is formed whereupon an LSC receives direct illumination and a second optical element that functions as a luminescent light source receives light transmitted through the LSC and redirect light at longer wavelengths towards the LSC. For example and referring to FIG. 9, chromophores 944 may be disposed in or on a substrate 190, with PV cells 120, forming an LSC. Following absorption of light 140, the chromophore 944 can reradiate a photon of equal or lesser energy. Thus, energy from the absorbed solar radiation is re-radiated by the chromophore 944. The chromophores 944 are physically oriented such that the emitted light is preferentially directed towards the direction parallel to the flat entrance face of the LSC. Light confinement is the LSC is desirably maximized. By physically orienting the chromophore dipole axis to be perpendicular to the front entrance face of the LSC, a large fraction of the emitted light will be directed parallel to the front entrance face of the LSC, and be confined within the LSC and directed towards the PV cells.

The chromophores in the LSC are desirably oriented with dipole axes perpendicular to the front surface face of the LSC. Exact perpendicular orientation is not necessary, and an increase in system power output may be achieve with orientation within an angular range. Illustrative dipole orientation may include, but are not limited to, between 0° and 30° from the direction perpendicular to the front light receiving surface, more particularly 0° to 20°, for example, about 0° to 15°.

The chromophores 946 disposed in or on the luminescent light source are not controllably oriented and the dipole axes are randomly oriented, resulting in a far-field isotropic emission pattern. Some portion of the re-radiated light may travel to the rear or edge faces of the luminescent light source, where one or more reflective surfaces 970 and 972 reside.

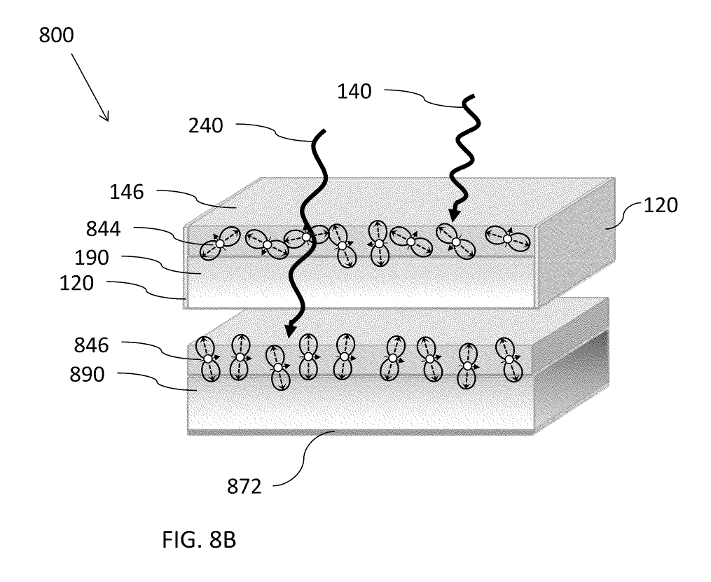

In one embodiment, a system 1000 is formed whereupon an LSC receives direct illumination and a second optical element that functions as a luminescent light source receives light transmitted through the LSC and redirect light at longer wavelengths towards the LSC. For example and referring to FIG. 10, chromophores 1044 may be disposed in or on a substrate 1091, with PV cells 120, forming an LSC. Following absorption of light 140, the chromophore 1044 can reradiate a photon of equal or lesser energy. Thus, energy from the absorbed solar radiation is re-radiated by the chromophore 1044. The chromophores 1044 are physically oriented such that the emitted light is preferentially directed towards the direction parallel to the flat entrance face of the LSC. Light confinement is the LSC is desirably maximized. By physically orienting the chromophore dipole axis to be perpendicular to the front entrance face of the LSC, a large fraction of the emitted light will be directed parallel to the front entrance face of the LSC, and be confined within the LSC and directed towards the PV cells.

The chromophores in the LSC are desirably oriented with dipole axes perpendicular to the front surface face of the LSC. Exact perpendicular orientation is not necessary, and an increase in system power output may be achieve with orientation within an angular range.

Illustrative dipole orientation may include, but are not limited to, between 0° and 30° from perpendicular, more particularly 0° to 20°, for example, about 0° to 15°.

The chromophores may be desirably oriented in the luminescent light source. For example and referring to FIG. 10, chromophores 1046 may be disposed in or on a substrate 1090, forming a luminescent light source. Following absorption of light 240 transmitted through an LSC, the chromophore 1046 can reradiate a photon of equal or lesser energy. Thus, energy from the absorbed solar radiation is re-radiated by the chromophore 1046. The chromophores 1046 are physically oriented such that the emitted light is preferentially directed towards the direction perpendicular to the flat entrance face of the luminescent light source. Light confinement is the luminescent light source is desirably minimized. By physically orienting the chromophore dipole axis to be parallel to the front entrance face of the luminescent light source, a large fraction of the emitted light will be directed perpendicular to the front entrance face of the luminescent light source, and exit the luminescent light source in a trajectory bound for the LSC. An optional reflective surface 1072 may be attached to the opposing face of the luminescent light source, which functions to increase the intensity of light redirected towards the LSC.

The chromophores in the luminescent light source are desirably oriented with dipole axes parallel to the front surface face of the luminescent light source. Exact parallel orientation is not necessary, and an increase in system power output may be achieve with orientation within an angular range. Illustrative dipole orientation may include, but are not limited to, between 0° and 30° from parallel, more particularly 0° to 25°, for example, about 0° to 20°.

The chromophores disposed in or on the LSC and luminescent light source may be chosen to satisfy the design criteria espoused in the description of FIG. 4.

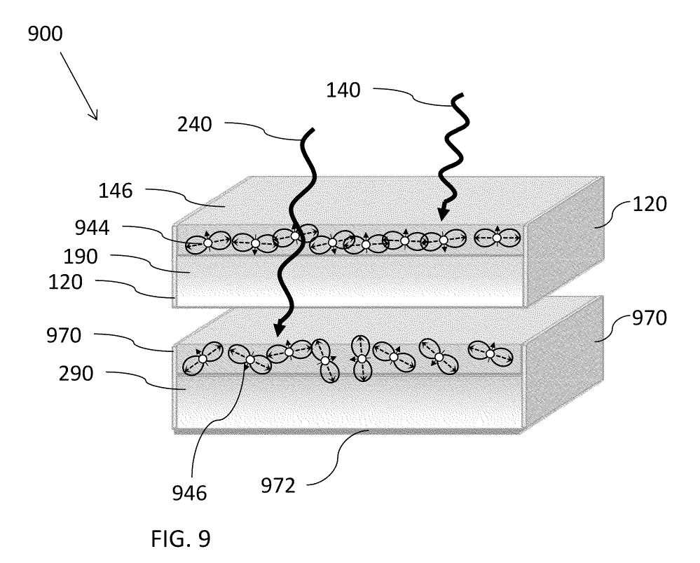

Coatings on the front surface of the LSC may serve to protect the LSC front surface from contamination. For example and referring to FIG. 11, an LSC 1142 has coatings 1183 and 1181 which reside between the chromophores 1144 disposed in or on the substrate 1148 and the ambient environment from which light 1140 is incident.

The efficiency by which the LSC transports confined luminescence is affected by surface contaminants. Residue, dust, oils, water, and minerals that are deposited on the module face from the surrounding environment serve to out-scatter confined light from the LSC, reducing optical flux gain.

Total internal reflection occurs when light is incident above the angle of total internal reflection from a medium of higher refractive index. Any coatings which are intended for LSC environmental protection will also transport light if they possess a refractive index which is substantially similar to the refractive index of the LSC. All LSC materials which transport light must be highly transparent and have a low density of scattering defects, or the optical transport efficiency will decrease and less light will reach the PV cells 1120 for electrical conversion.

The LSC coating 1183 is chosen to have a very low refractive index. In doing so, the coating provides the change in refractive index which total internally reflects the luminescent light. Due to the low refractive index, the coating does not transport the confined light. For The luminescence confinement efficiency increases as the index of refraction mismatch between the substrate and the surrounding media is increased. If the coating 1183 has an index of refraction above 1 but below 1.4, a substantial amount of light will still be confined to the LSC substrate 1148 and will not experience surface contaminants on coating 1183 and will be shielded from environmental contaminant induced out-scatter. Examples of coatings with refractive indices suitable for LSC protective layers are described in M. L. Kuo, D. J. Poxson, Y. S. Kim, F. W. Mont, J. K. Kim, E. F. Schubert, and S. Lin, Optics Letters 33 (21), 2527-2529.

Additional optional coating(s) 1181 may be placed on top of coating 1181 to reduce unwanted reflection of incoming light or to protect the low refractive index coating 1183 from physical or chemical breakdown. Examples of coatings with properties suitable for LSC low refractive index protective layers are described in M. L. Kuo, D. J. Poxson, Y. S. Kim, F. W. Mont, J. K. Kim, E. F. Schubert, and S. Lin, Optics Letters 33 (21), 2527-2529.

Systems utilizing a single LSC without a luminescent light source based on inorganic chromophores in glasses are described in, for example, R. Reisfeld, and Y. Kalisky, Nature 283 (5744) 281-282. These systems absorb sunlight and concentrate infrared light. However, they exhibit low broadband spectral absorption efficiency, and a substantial fraction of light is transmitted through the LSC without being collected. Systems utilizing a single LSC without a luminescent light source based on organic chromophores coated onto glass are described in, for example, M. J. Currie, J. K. Mapel, T. D. Heidel, S. Goffri, and M. A. Baldo, Science 321 (5886) 226-228. Such systems absorb sunlight and concentrate visible light and can exhibit high spectral absorption efficiency through the use of near field Forster energy transfer among multiple chromophore species.

To achieve the highest power conversion efficiency, it is desirable to utilize a PV cell with an optical bandgap that is close in energy to that of the luminescent light. Satisfying this criterion reduces power loss between the photon energy and PV cell output voltage. For example, confined infrared luminescence from inorganic chromophores is desirably coupled to PV cells with an infrared optical bandgap. As another example, confined visible luminescence from organic chromophores is desirably coupled to PV cells with a visible optical bandgap.

In a system comprised of an LSC and a luminescent light source, light absorption may occur in both the LSC and the luminescent light source. As such, it is possible to utilize an inorganic chromophore to collect and concentrate parts of the infrared and visible solar spectrum and organic chromophores to collect and redirect visible parts of the solar spectrum. In this way, light can be collected over a larger fraction of the solar spectrum, increasing absorption efficiency and power conversion efficiency. For example, inorganic chromophores such as neodymium ions in phosphate glass may form the luminescent emitters in the LSC, and organic chromophores such as perylene diimides may form the luminescent emitters in the luminescent light source.

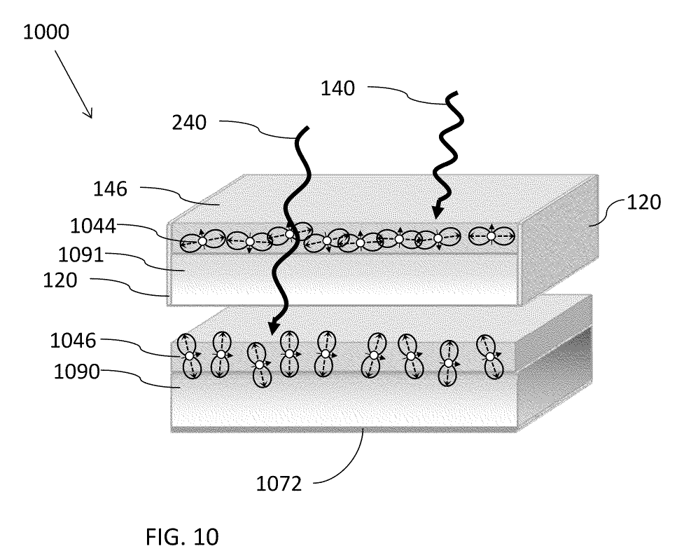

In the current and previous embodiments, the PV cells which convert the light to electricity may be attached to various surfaces of the LSC, exclusively or when used with a luminescent light source, including selected portions of the back, exclusively or in addition to selected portions of one or more edge faces. For example and referring to FIG. 12, an LSC 1242 has PV cells 1289 attached to the rear surface of the light guiding substrate 1248 by polymer films of ethylene vinyl acetate (EVA) 1285 and 1287. The PV cells are attached in linear arrays spanning the LSC length or width. The cell lines, or strings, may be distributed such that each PV cell in the string receives a substantial similar light intensity as others in the array.

The ratio of the light collection area to the PV cell area is known as the geometric concentration factor and is directly related to the reduction in PV cell cost as a fraction of the overall PV module. The cells should be sized and placed in a manner to maximize the electrical flux gain of the system. To accomplish this, a high optical coupling efficiency between the LSC and PV cells is desirable. This is possible if, for instance, the width of the PV cells and string, denoted n, is substantially larger than the thickness of the LSC substrate, denoted t. A range of PV cell dimensions is possible to increase coupling efficiency. For example, w≧2t. Optical coupling efficiency increases as the ratio of w/t increases, but the geometric concentration factor decreases in concert. The value of w/t that maximizes electrical flux gain for maximal cost reduction depends on the relative costs of the various module components, but in general a value of w/t between 2 and 7 is suitable for PV cells comprised of silicon.

Ethylene vinyl acetate films for encapsulation of PV cells on the flat glass plates is typical in PV module manufacturing and these and similar materials may be utilized for PV cell attachment in this embodiment where the PV cells are attached to the rear surface.

In the current embodiment, light that reaches the LSC edge faces may be redirected inwards for optical coupling to the PV cells through the use of reflective surfaces 1249 attached to the edges faces. In some instances, the reflective surfaces may be directly attached to the LSC, while in others, the reflective surface may be separated from the LSC by a gap filled with air or other gases. The reflective surfaces may be of any type that may function to reflect light, include mirrors made of metal or dielectrics, multilayer dielectric stacks, or diffuse reflectors formed from rough, white pigments or oxides. The reflective surface may be directly applied onto the LSC edge face or the reflective surface may reside on a self-supporting film which may be laminated to the LSC.

To both maximize the efficiency of optical coupling from the LSC to the PV cells and to facilitate current collection from the PV cells, it is desirable to utilize PV cells which do not have electrodes on the surface that is attached to the LSC. Such PV cells are referred to as back-contact cells and are described in, for instance, W. P. Mulligan, D. H. Rose, M. J. Cudzinovic, D. M. DeCeuster, K. R. McIntosh, D. D. Smith, R. M. Swanson, Proceedings of the 19^{th} European Photovoltaic Solar Energy Conference, Paris, France (2004); A. Blakers “Silicon concentrator solar cells,” in A. Luque, V. Andreev eds. Concentrator Photovoltaics, Springer-Verlag Berlin (2007). As electrode surface do not absorb light that is convertible to electrical current in PV cells, back contact cells reduce optical coupling losses by reducing the electrode area exposed to confined luminescence.

To reduce losses in efficiency during the back transfer of light energy from the luminescent light source to the LSC, it is desirable to contact the PV cells using electrical conductors that do not block light in addition to that shadowed by the PV cell. This can be accomplished, for example, by using tinned copper ribbon wire that are directly soldered onto the contact pads of the PV cells. Other materials for the electrical conductors can be used and will be recognized by the person of ordinary skill in the art, given the benefit of this disclosure.

It is desirable to alter the PV cell structure compared to cells designed for solar illumination to maximize optical coupling efficiency. Broadband anti-reflection coatings are typically chosen to increase power conversion efficiency for solar illumination. When coupled to a system comprised of an LSC and a luminescent light source, PV cells are exposed to illumination that is much narrower in comparison to the sun. For example, see FIG. 4. As such, the characteristics of a PV cell anti-reflection coating (for instance, thickness or refractive index) can be adjusted to reduce unwanted reflections at the luminescence wavelength.

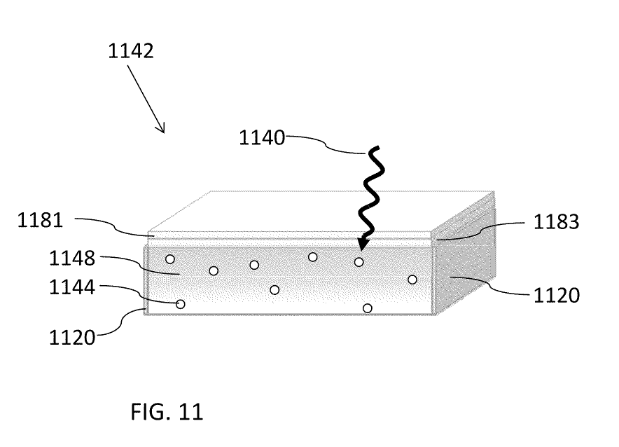

Light absorption efficiency can be increased through the use of additional luminescent light sources. FIGS. 13-15 are cross sectional view of systems comprised of an LSC and two or more luminescent light sources which has been vertically exploded for visual clarity. For example and referring to FIG. 13, an LSC 1348 with rear surface mounted PV cells 1320 partially transmits light to luminescent light sources 1351 and 1355 separated by light scattering materials 1353 and 1357, which are supported by a glass mirror 1359.

In certain embodiments, it is desirable to separate light absorption into separate luminescent light sources rather than utilizing several chromophores in a single luminescent light source. For example, if the chromophores utilized in the luminescent light source 1351 emit light at a higher energy than the chromophores utilized in the luminescent light source 1355 and the chromophores utilized in the luminescent light source 1351 emit light at a higher photoluminescence efficiency than the chromophores utilized in the luminescent light source 1355, an increase in overall luminescence intensity from the combined system of two luminescence light sources is possible compared to the case in which both chromophores are included in a single luminescent light source.

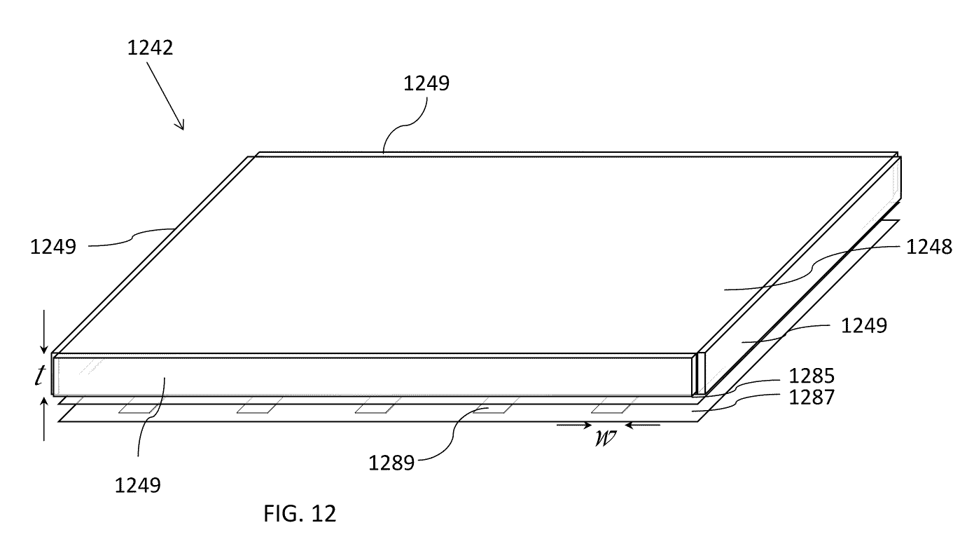

One of the luminescent light sources may be coated directly onto the LSC to achieve a similar separation of luminance sources. For example and referring to FIG. 14, an LSC 1448 with a luminescent coating 1467 and rear surface mounted PV cells 1420 partially transmits light to a second luminescent light source 1461 which is above a light scattering material 1463, which is supported by a glass mirror 1465.

In certain embodiments, it is desirable to separate light absorption into separate luminescent light sources rather than utilizing several chromophores in a single luminescent light source. For example, if the chromophores utilized in the luminescent light source 1467 emit light at a higher energy than the chromophores utilized in the luminescent light source 1461 and the chromophores utilized in the luminescent light source 1467 emit light at a higher photoluminescence efficiency than the chromophores utilized in the luminescent light source 1461, an increase in overall luminescence intensity from the combined system of two luminescence light sources is possible compared to the case in which both chromophores are included in a single luminescent light source.

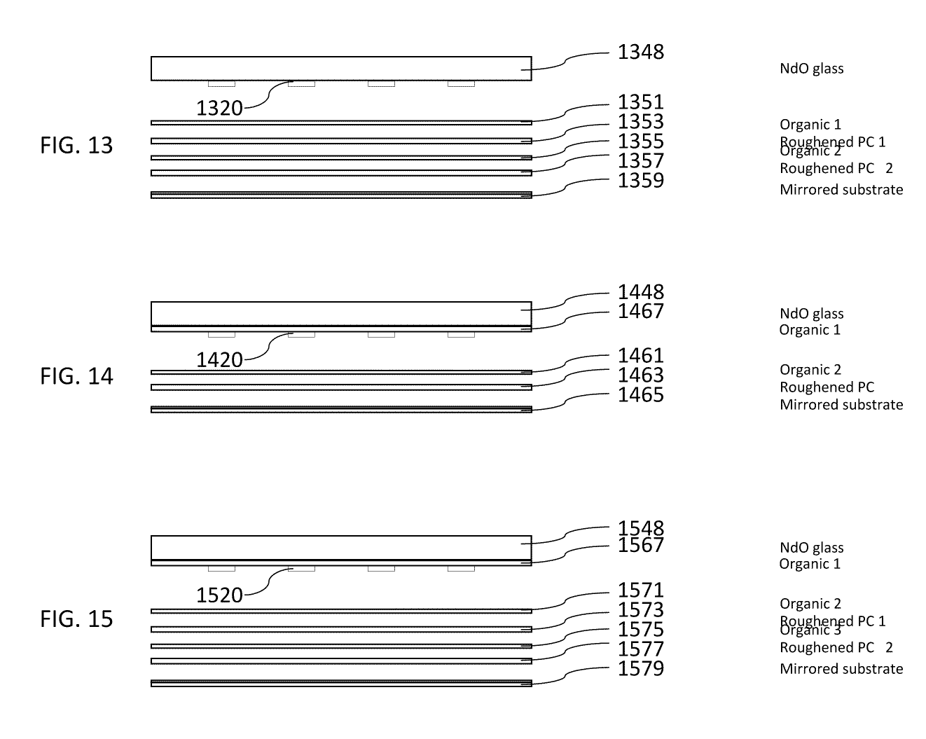

Three or more luminescent light may be used in a system with an LSC, where one of the sources may be coated directly onto the LSC to achieve a similar separation of luminance sources. For example and referring to FIG. 15, an LSC 1548 with a luminescent coating 1567 and rear surface mounted PV cells 1520 partially transmits light to luminescent light sources 1571 and 1575, which separated by light scattering materials 1573 and 1577, which are supported by a glass mirror 1579.

In certain embodiments, it is desirable to separate light absorption into separate luminescent light sources rather than utilizing several chromophores in a single luminescent light source. For example, if the chromophores utilized in the luminescent light source 1567 emit light at a higher energy than the chromophores utilized in the luminescent light source 1571 which emit light at a higher energy than the chromophores utilized in the luminescent light source 1575 and the chromophores utilized in the luminescent light source 1567 emit light at a higher photoluminescence efficiency than the chromophores utilized in the luminescent light source 1571 which emit light at a higher energy than the chromophores utilized in the luminescent light source 1575, an increase in overall luminescence intensity from the combined system of three luminescence light sources is possible compared to the case in which both chromophores are included in a single luminescent light source.

The systems described in FIGS. 13-15 may be utilized with more than two or three luminescence light sources, as will be recognized by the person of ordinary skill in the art, given the benefit of this disclosure.

The multi-coating stack which comprises the luminescent light source or sources may be formed from the coating of multiple layers directly onto a supporting substrate, or they may be produced in thin self-supporting films that are laminated together.

In certain embodiments, LSC light absorption materials may not absorb incident light with high efficiency. It is desirably to have a light absorption efficiency of 100%. Incomplete absorption could arise in several circumstances. For instance, the doping density of chromophores may be reduced in order to reduce optical transport losses. In this situation, the chromophore doping density may be chosen to maximize total device performance, but the LSC light absorption materials may still transmit large amounts of light. In another circumstance, a light absorption material may be used that has a low absorption coefficient for over some spectral range of light. In this situation, a substantial amount of light may pass through the light absorption material. A possible remedy for this situation would be to increase the doping density of chromophores, but this may sometimes decrease the efficiency of photoluminescence through a process known as concentration quenching. A doping density that maximizes the factor of the absorption and photoluminescence efficiencies is desired in order to increase total device performance, but it is still desirable to increase absorption efficiency to as close to 100% as possible if other processes are not diminished in efficiency. Another possible remedy to increase light absorption in a material with a low absorption coefficient is to increase the thickness of the light absorbing material. This may be impractical due to weight density or cost constraints. For instance chromophores doped at low densities into a bulk matrix material like glass may require thicknesses greater than 1-10 cm in order to fully absorb incident light. Typical glass used in silicon PV modules is 0.2-0.7 cm; glass with thicknesses of 1-10 cm will substantially increase the weight density of an LSC solar module, increasing transportation, handling, and installation costs, which is undesirably. Additionally, the cost per unit area of a light guide material like glass strongly depends on thickness, as thicker media use more raw materials in their manufacture.

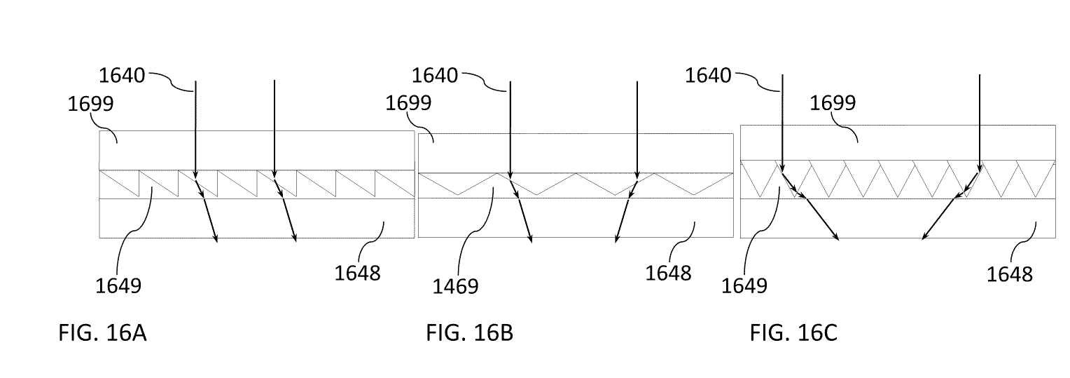

FIG. 16A shows an example of an alternative remedy for increasing light absorption in absorption-limited materials. FIGS. 16A-C are device cross sections. Incident sunlight 1640 first encounters a light turning layer 1699 before encountering the LSC 1648. The front and rear surfaces of the light turning layer are substantially non-parallel, and the light turning layer 1699 is comprised of a material with a refractive index greater than the media which are adjacent to its front and rear surfaces. As light passes through the light turning layer, it may be uniformly redirected such that the angle of incidence of light onto the LSC 1648 is greater than the angle of incidence of light onto the light turning layer 1699. The light turning layer and the LSC may be separated by a material 1649 with a refractive index lower than both the light turning layer and the LSC.

The front and rear surfaces of the light turning layers are substantially non-parallel; their exact shapes can range widely. The shapes affect the angle at which light turns and the focal point to the redirected light, if any. FIG. 16A shows an example of a light turning layer 1699 that has a front surface that is flat (perpendicular to incoming sunlight) and a rear surface that is angled. The angular pitch is such that incoming light predominantly refracts such that it may enter the LSC at a higher angle of incidence. FIG. 16B shows an example where the angular pitch of the rear surface alternates between two angles, such that all light is not turned the same direction. FIG. 16C shows an example where the angular pitch of the rear surface is such that incident light is predominantly totally internally reflected (like a prism), but the angular pitch on a nearby portion of the rear surface is such that on subsequent encounters with the rear surface, it is substantially transmitted by refraction. Examples of prism sheets that may function as light turning layers in LSCs are described in U.S. Pat. Nos. 5,851,062 and 5,844,720.

Increasing the angle of incidence of incoming light is desirable for several reasons. The total light absorption efficiency is dependent on the optical interaction path length. The effective path length is increased when light is incident at an angle greater than 0 degrees. Once light has entered the light absorption material, it is desirable to increase its travel distance to the greatest length possible in order to increase the amount of time the light and matter interact such that the light absorption efficiency is increased.

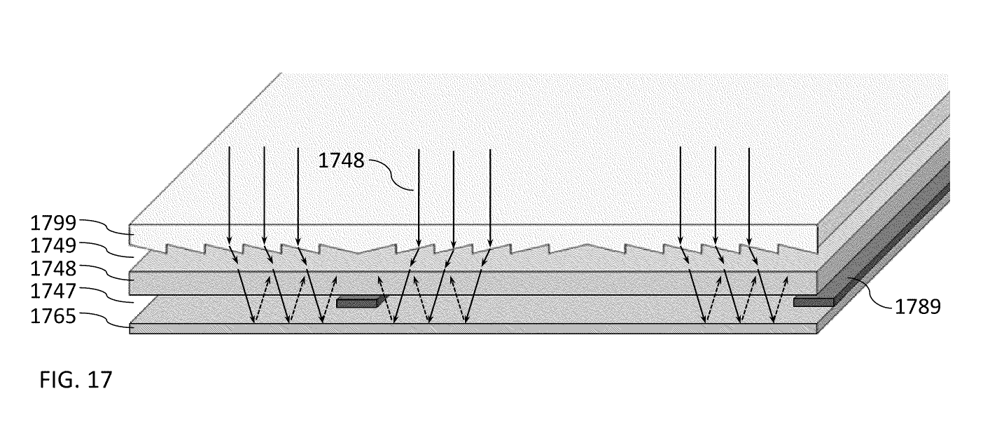

FIG. 17 shows an example of an alternate configuration of light turning layers and LSCs. A light turning layer 1799 redirects light to higher angles of incidence after its passage through a lower refractive index medium 1749. Despite the longer pathlength of light through the LSC 1748, some light may still be transmitted. A rear reflective element 1765 separated by a medium of lower refractive index 1747 redirects light back into the LSC 1748 for a second pass. If the rear reflective element is a planar metallic reflector, the angle of incidence and angle of reflection will be identical, and the light will make its second pass through the LSC with an angle of incidence upon the rear surface of the LSC will be greater than the angle of incidence of sunlight incident on the front surface of the light turning layer. The increase in optical path length introduced by the light turning layer will be further increased in its second pass.

After light has been absorbed by the LSC, emitted light is guided until it is converted to electricity by a PV cell 1789. When the optical transport efficiency is less than 100%, it is desirable to minimize the distance that the confined light must travel to reach to PV cell. Certain light turning layers can desirably decrease this distance. For example and referring to FIG. 17, the rear surface of the light turning layer is patterned such that light is line focused, forming a one dimensional Fresnel lens. The focal distance may be greater than the separation distance between the lens and the LSC, but the lens still functions to decrease the distance between the initial absorption event and the PV receiver such that optical transport losses are reduced.

Light turning layers are used frequently as in liquid crystal displays to alter the direction of light emitted by a backlight before it reaches the liquid crystal layer. 3M Corporation distributes several such films (Vikuiti Transmissive Right Angle Film TRAF II, Vikuiti Rounded Brightness Enhancing Film RBEF, Vikuiti Image Directing Film IDF II, Vikuiti Wave Brightness Enhancing Film WBEF, and Vikuiti Brightness Enhancing Films BEF III and BEF III-10T. In liquid crystal displays, they are utilized in reverse: light is incident upon the non-perpendicular surface (angle of incidence is greater than zero) to be redirected to a lower angle of incidence.

The inclusion of light turning layers may introduce unwanted reflections at its top and bottom surfaces, negating the benefit of increased optical pathlength as less light enters the light turning layer. To reduce these reflections, anti-reflection coatings may be optionally included. The types and thicknesses of coatings to decrease reflections are well known and will be recognized by one skilled in the art.

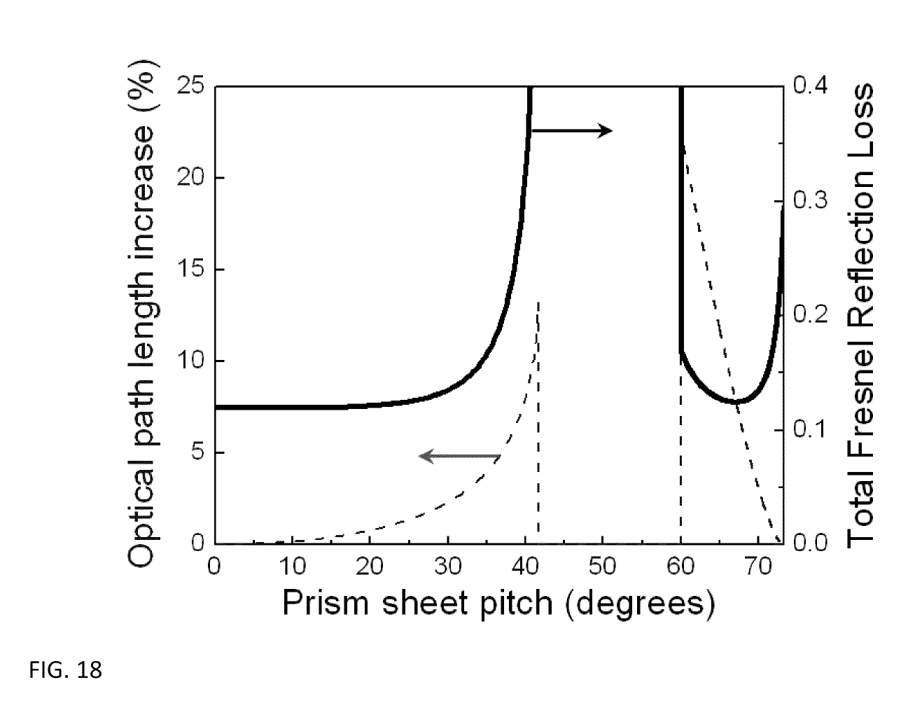

FIG. 18 shows the change in optical path length when a simple prism sheet (refractive index 1.5) comprised of a planar front surface and a pitched rear surface is placed in front of an LSC (refractive index 1.5) and separated by air (refractive index 1.0). The prism pitch is defined as the angle between the angled back surface and the plane formed by the front surface. In this simple geometry the rear surface pitch has little effect when its angle is between 0 and 20 degrees. The optical path length increases as the pitch angle approaches −42 degrees. Between 0 and −42 degrees, light is redirected according to FIG. 16A. As the angle pitch increases between 42 and 60 degrees, light is total internally reflected twice, such that the light never enters the LSC. For an angular pitch between 60 and −75 degrees, light is redirected according to FIG. 16C, where a single total internal reflection event precedes one or more refractions before reaching the LSC. FIG. 18 shows that the maximum optical path length increase occurs for angles near 61 degrees. FIG. 18 also shows the additional Fresnel reflection losses introduces when no anti-reflection coatings are present.

The shape of the front and rear surfaces of the light turning sheet need not be planar. One or both surface may have planar and rounded sections, and each section may be different from others on the overall sheet. FIGS. 16A-C and FIG. 17 are examples. In general the exact shape of the front and rear surfaces will depend on the shape of the LSC and the location of one or more PV cells. For each possible LSC shape and PV cell layout, there will be an optimum front and rear surface shapes for the light turning layer to maximize total energy generation from the complete system.

Rare earth metal-, lanthanide metal-, and transition metal-doped glasses have been developed and implemented in solid state lasers. These dopants may serve several purposes in a solid state glass laser. The primary lasing dopant possesses energy levels that produce stimulated emission of light when placed in an optical amplifier. The emissive energy levels may be populated through direct optical absorption of light from a flashlamp or semiconductor diode light source, as described in W. Koechner, Solid-State Laser Engineering, 6^{th} Ed., Springer, New York (2006). Auxiliary dopants may absorb light in spectral regions of the flashlamp away from the spectral regions of the primary dopant and transfer the energy to the primary dopant, thus improving the overall efficiency of the laser.

Like solid state lasers, LSCs may be comprised of rare earth metal-, lanthanide metal-, and transition metal-doped glasses. Primary dopants may be desirably utilized to generate confined luminescence to be concentrated onto a PV cell. In some examples, the primary may not absorb incident sunlight with high efficiency, and it is desirable to sensitize the primary dopant with auxiliary dopants that absorb light in spectral regions away from the spectral regions of the primary dopant and transfer the energy to the primary dopant, thus improving the overall efficiency of the LSC.

The sensitized LSC glass of the present invention includes primary emitting dopant chromophores of a rare earth metal or transition metal and auxiliary dopants of transition metals or quantum dots. The primary dopants in the sensitized LSC glass composition of this invention are neodymium, ytterbium, or vanadium. The primary dopants are incorporated in their oxide forms with valency 3+, 3+ and 4+, respectively, and not covalently bonded to carbon atoms or forming organomettalic complexes. The auxiliary dopants in the sensitized LSC glass composition of this invention are cerium, manganese, titanium, chromium, neodymium, ytterbium, or lead sulfide quantum dots. The effective concentration of the primary dopant is between 0.5 and 12 percent by weight. Hereafter, all percentages are given by weight. Single or multiple auxiliary dopants with identical or differing doping levels may be utilized to sensitize the primary dopant. The effective concentration of the auxiliary dopants is between 0.25% and 12%. The glass matrix may be comprised of several glass compositions, including potassium aluminosilicate phosphate glass, silicate glass, other phosphate glasses, silicate-phosphate glasses, sodium, lithium, tellurite, borosilicate glass, and crown glass.

The sensitized LSC glass of this invention provides substantial improvement in absorption efficiencies over the prior art. Researchers developing sensitized glass compositions for flashlamp-pumped solid state lasers have utilized cerium, manganese, titanium, chromium, and lead sulfide quantum dots as candidates for auxiliary dopants because the elements absorb in the regions of the flashlamp spectrum spaced from the absorption bands of the primary dopant, particularly neodymium. The preferred candidates for auxiliary dopants have emission spectra which overlaps the absorption bands of the primary dopant, such that energy transfer from the auxiliary dopant to the primary dopant occurs. Tests conducted on laser glasses utilizing this scheme have been successful, including cooperative sensitization of neodymium by titanium and manganese (E. B. Kleshchinov, I. M. Batyaev, S. M. Begel'dieva, D. V. Kharitonov, Technical Physics Letters 28, 441-443 (2002) and cooperative sensitization of neodymium by cerium and chromium (Meyers, U.S. Pat. No. 4,770,811)).

It is understood from absorption spectra of the primary and auxiliary dopants and the incident light spectra from flashlamps and the sun that efficient energy transfer from these auxiliary dopants to the primary dopant under solar illumination will occur with high efficiency in LSCs. Cerium, manganese, titanium, and chromium ions in various glasses have strong and broad absorption bands that do not substantially overlap the absorption bands of neodymium or ytterbium. Lead sulfide quantum dots have optical properties that are adjustable and dependent on the dimensions of the quantum dot due to quantum confinement. Certain lead sulfide quantum dots have an absorption spectrum that does not substantially overlap the absorption bands of neodymium, ytterbium, or vanadium. The emission spectra of cerium, manganese, titanium, chromium, and certain lead sulfide quantum dots have an emission spectrum that substantially overlaps with the absorption bands of neodymium, ytterbium, and vanadium.

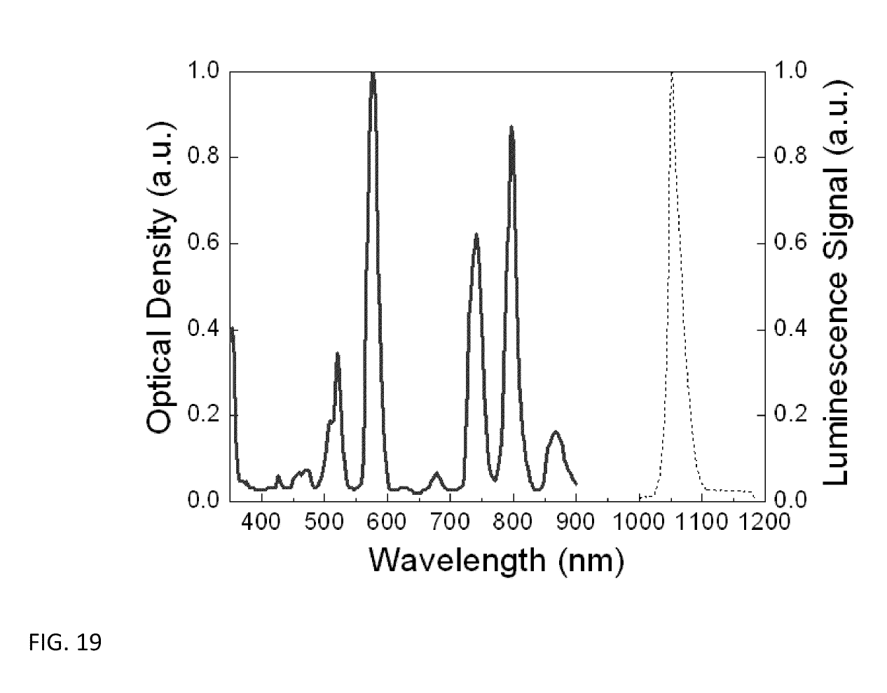

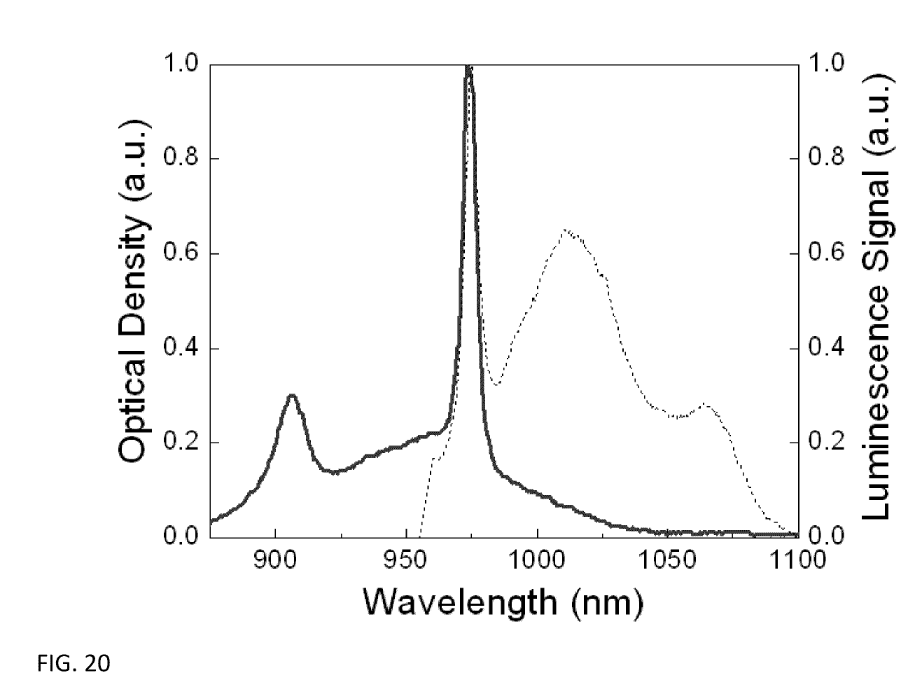

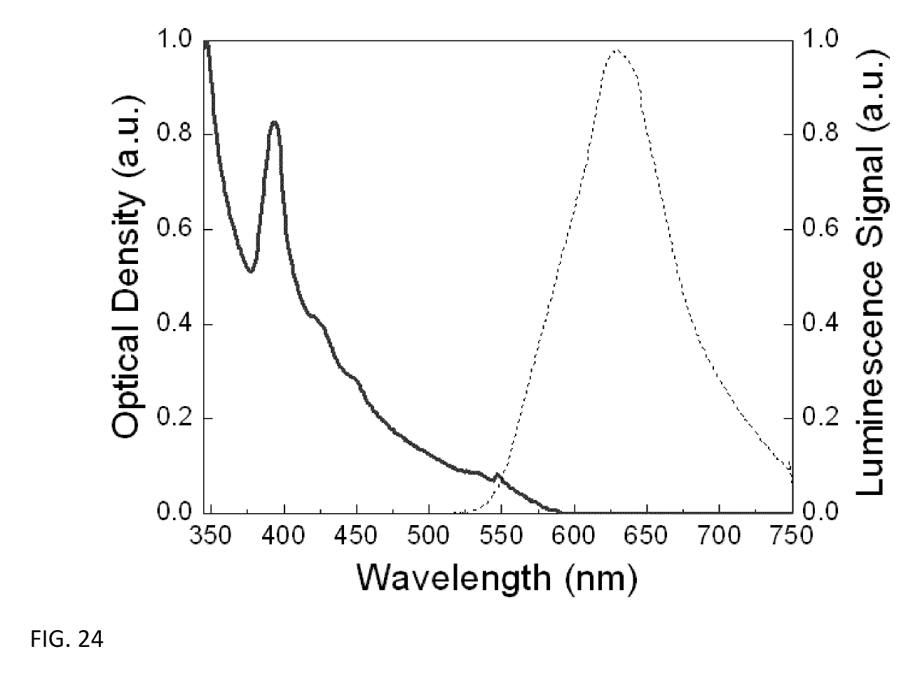

FIG. 19-24 show multiple examples of the optical spectra of several dopants appropriate for use in LSCs. FIG. 19-21 show examples for systems comprised of a single primary dopants in glass, and FIGS. 20-23 show examples for systems comprised of single secondary dopants in glass. FIGS. 24-26 show examples of one or more secondary dopants and single primary dopants in glass.

FIG. 19 shows the optical density (solid line) of Nd ions in phosphate glass with a composition of 22.1% Al(PO₃)₃-58.7% BaF₂-17.2% AlF₃-2% Nd₂O₃ by weight, from R. Balda, J. Fernandez, A. Pablos, J. M. Fernandez-Navarro, Physical Review B, 48, 2941-2948 (1993). FIG. 19 also shows the luminescence (dotted line) spectrum of Nd ions in phosphate glass with a composition of 55% P₂O₅-30% Li₂O-10% CaO-4.3% Al₂O₃-0.7% Nd₂O₃ (mol %), from M. J. Weber, Journal of Non-Crystalline Solids 123, 208-222 (1990).

FIG. 20 shows the optical density (solid line) and luminescence (dotted line) spectra of Yb ions in silicate glass with a composition of 58.0% SiO₂-23.8% PbO-5.7% NaO-5% Yb₂O₃ (mol %), from N. Dai, L. Hu, P. Lu, Optics Communications, 253, 151-155 (2005).

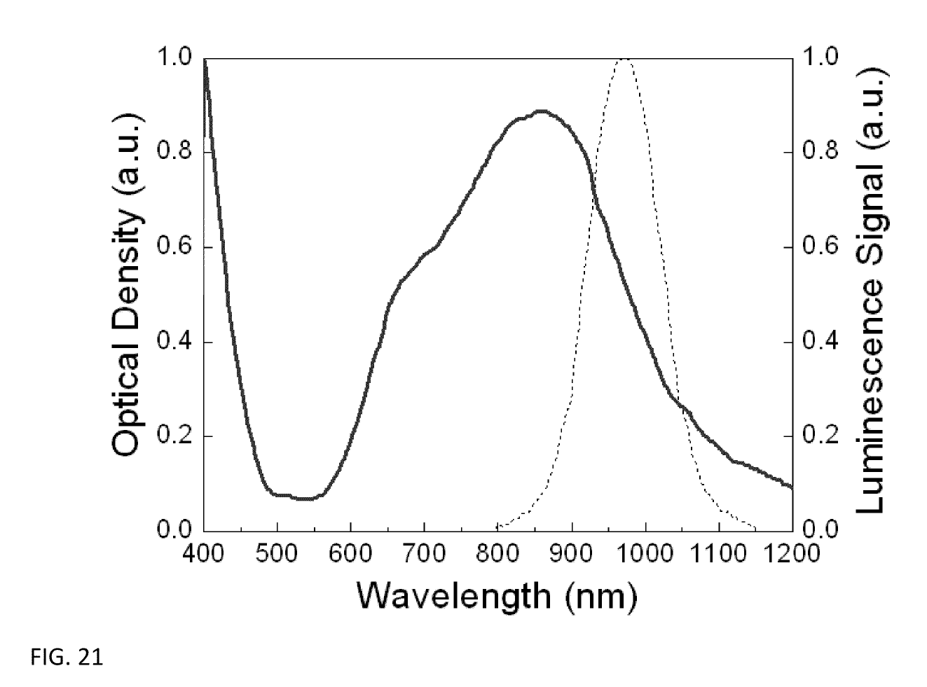

FIG. 21 shows the optical density (solid line) and luminescence (solid line) spectra of vanadium ions in phosphate glass with a composition of 59.1% P₂O₅-23.6% K₂O-17.1% Al₂O₃-0.2% VO₂ (mol %), from I. M. Batyaev, S. V. Linnikov, A. L. Lipatova, Technical Physics Letters, 29, 327-328 (2003).

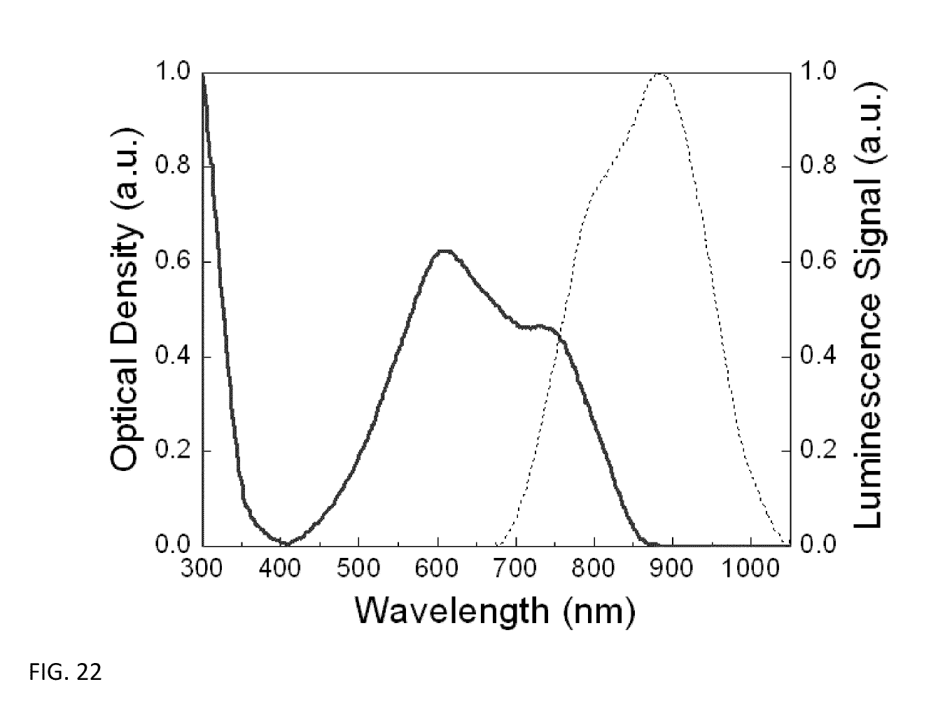

FIG. 22 shows the optical density (solid line) and luminescence (dotted line) spectra of Al(PO₃)₃:Ti³⁺ glass, from A. V. Aristov, D. A. Kozlovskii, I. M. Batyaev, Y. G. Kobezhikov, Journal of Optical Technology, 67, 209-215 (2000).

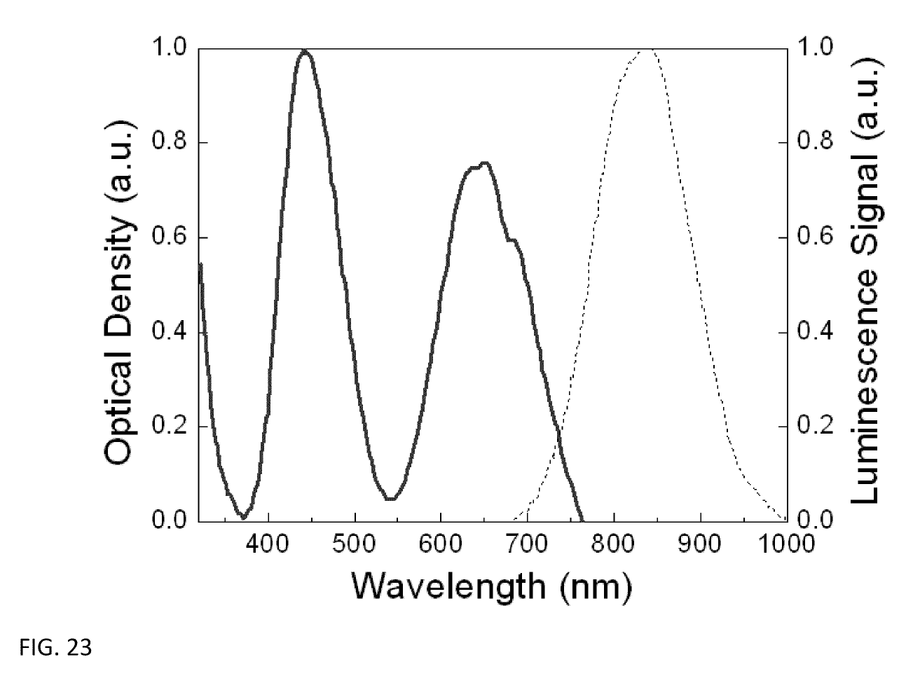

FIG. 23 shows the optical density (solid line) of chromium ions in phosphate glass with a composition of 22.4% Al(PO₃)₃-59.6% BaF₂-17.5% AlF₃-0.5% Cr₂O₃ by weight, from R. Balda, J. Fernandez, A. Pablos, J. M. Fernandez-Navarro, Physical Review B, 48, 2941-2948 (1993). FIG. 23 also shows the luminescence spectrum (dotted line) of Cr ions in barium phosphate KGSS-0135 glass, from Y. D. Berezin, N. V. Danil'chuk, S. G. Lunter, V. M. Mit'kin, Y. K. Federov, V. N. Shapovalov, Zhurnal Prikladnoi Spectroskopii, 40, 189-194 (1994).

FIG. 24 shows the optical density (solid line) and luminescence (dotted line) spectra of manganese ions in phosphate glass with a composition of 61% P₂O₅-18% K₂O-11% Al₂O₃-10% SiO₂: MnO₂ (1.8 mol %), from I. M. Batyaev, S. M. Begel'dieva, E. B. Kleshchinov, S. M. Shilov, Russian Journal of Applied Chemistry, 76, 1694-1695 (2003).

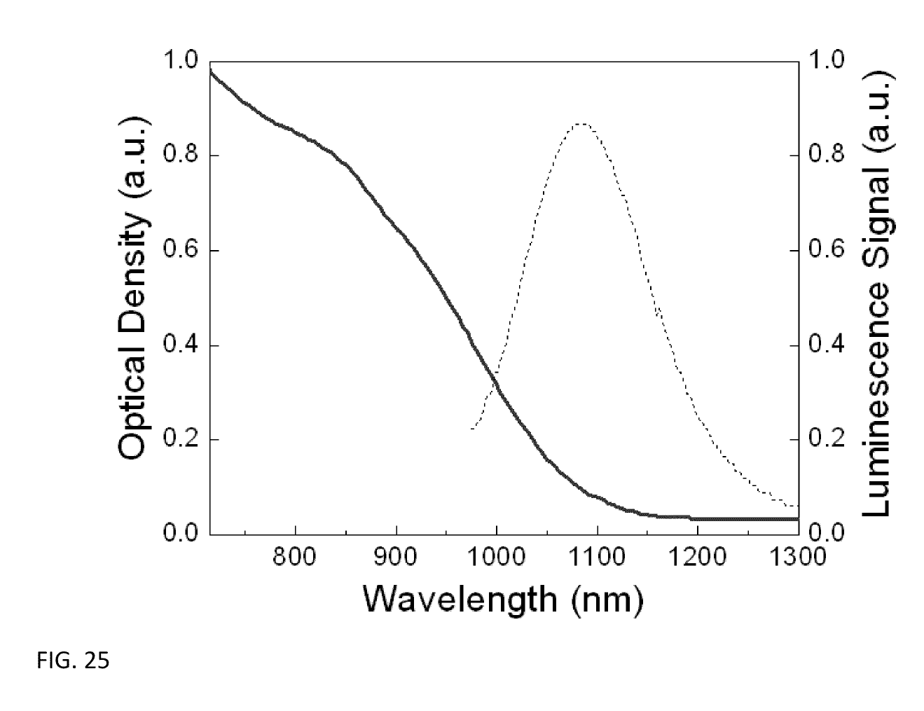

FIG. 25 shows the optical density (solid line) and luminescence (dotted line) spectra of lead sulfide quantum dots in phosphate glass with a composition of 65.4% SiO₂-7.9% B₂O₃-17.8% K₂O-4.0% SrO-1.0% PbS (mol %), from W. Huang, Y. Z. Chi, X. Wang, S. F. Zhou, L. Wang et al, Chinese Physics Letters, 25, 2518-2521 (2008).

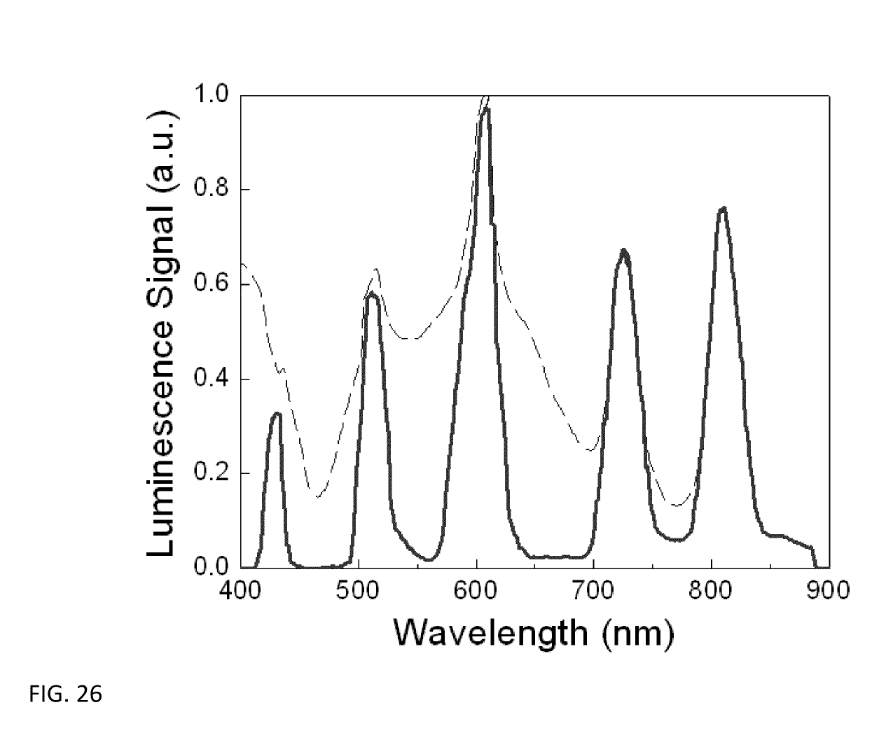

FIG. 26 shows the excitation of phosphate glass with a composition of 56.8% P₂O₅-22.8% K₂O-16.4% Al₂O₃ (mol %) with one primary (Nd 0.5% by weight, solid line) and with two auxiliary (Mn 3.0% and Ti³⁺ 3.0%, both by weight, dashed line) dopants, from E. B. Kleshchinov, I. M. Batyaev, S. M. Begel'dieva, D. V. Kharitonov, Technical Physics Letters 28, 441-443 (2002).

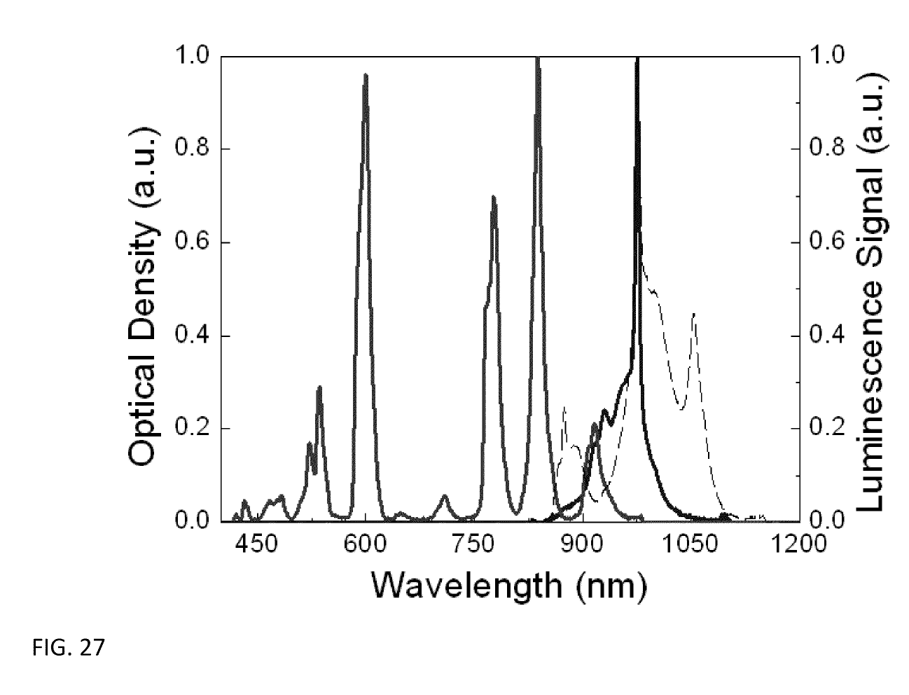

FIG. 27 shows the optical density (solid lines) spectra of lead metaphosphate (Pb(PO₃)₂) with one primary (Yb 5.0% mol percentage) and with one auxiliary (Nd 5.0% mol percentage, dashed line) dopant, and luminescence (dashed line) of a glass composition with both dopants, from F. Liégard, J. L. Doualan, R. Moncorgé, M. Bettinelli, Applied Physics B, 80, 985-991 (2005).

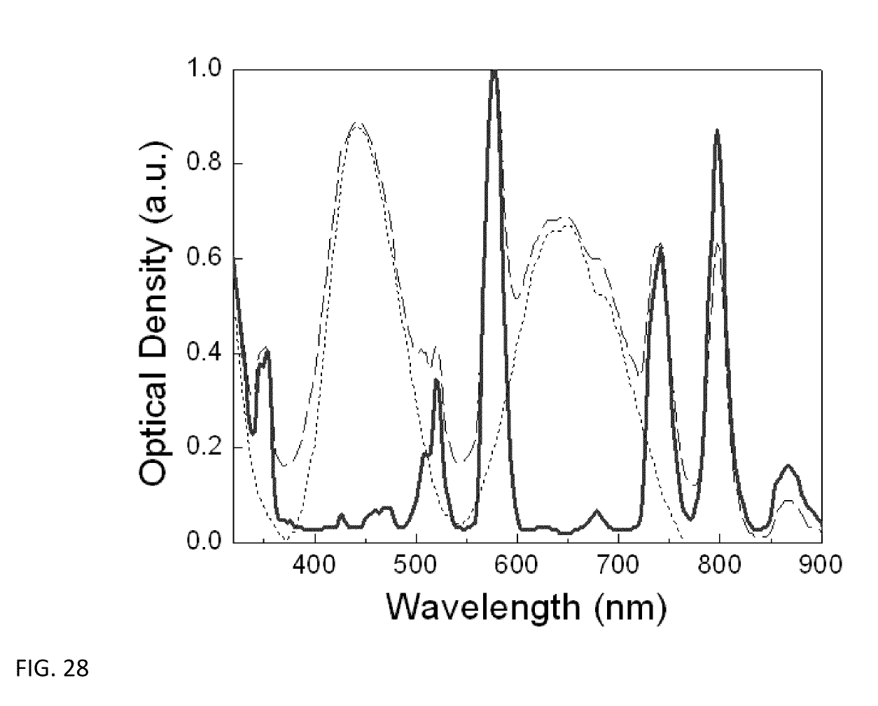

FIG. 28 shows the optical density of phosphate glass with a composition of 59.9% BaF₂-22.5% Al(PO₃)₃-17.6% Al₂O₃ (weight %) with one primary (Nd₂O₃ 2.0% by weight, solid line) and one auxiliary (Cr₂O₃ 0.5% by weight, dotted line) dopant, from R. Balda, J. Fernandez, A. Pablos, J. M. Fernandez-Navarro, Physical Review B, 48, 2941-2948 (1993). The optical density for the same glass with both dopants is also shown (dashed line).

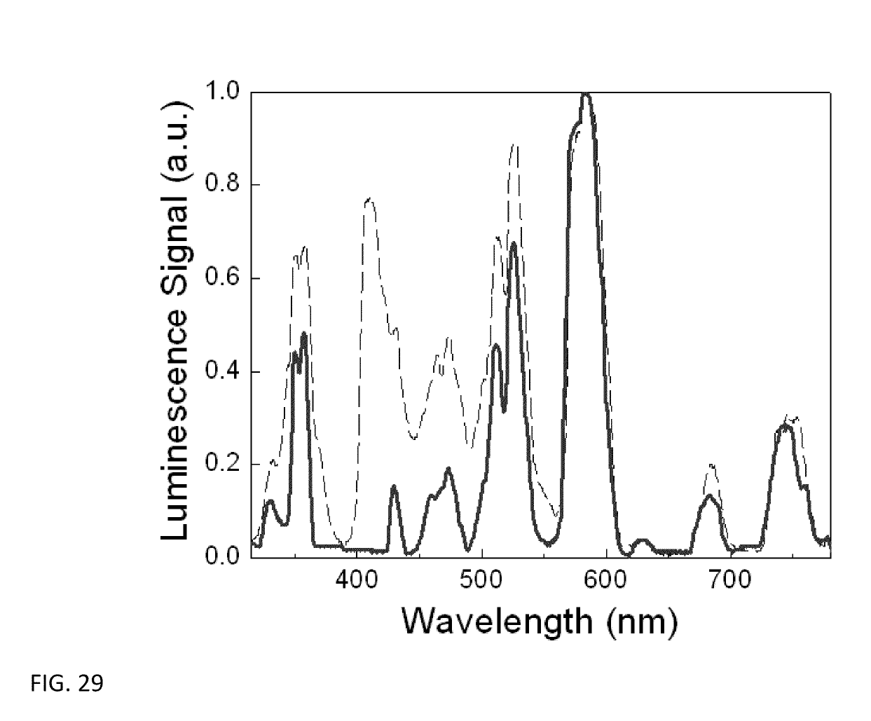

FIG. 29 shows the excitation of magnesium phosphate glass with a composition of with one primary (Nd₂O₃ 4.0% by weight, solid line) and one auxiliary ((Mn_{0.5}Mg_{0.5})(PO₃)₂, dotted line), from N. T. Melamed, C. Hirajama, E. K. Davis, Applied Physics Letters, 7, 170-172 (1965). The optical density for the same glass with both dopants is also shown (dashed line).

It will be further appreciated that the scope of the present invention is not limited to the above-described embodiments but rather is defined by the appended claims, and that these claims will encompass modifications and improvements to what has been described.

1. A remote sensitization solar concentrator for receiving sunlight and for communicating light of lower energy than the sunlight to an optically coupled solar cell, the solar concentrator comprising:
a substrate;
a primary chromophore, the primary chromophore operable to receive at least some optical radiation, the primary chromophore further effective to absorb at least one wavelength of at least some of the optical radiation, the primary chromophore luminescent in a spectral band that is absorbed by the solar cell;
an auxiliary chromophore, the auxiliary chromophore operable to receive at least some optical radiation, the auxiliary chromophore further effective to absorb at least one wavelength of at least some of the optical radiation;
an optical waveguide for confining and directing light emitted by the primary chromophore to an optical communication region, the waveguide comprising the substrate and at least one lower refractive index medium adjacent the front and rear surfaces of the substrate, such that light is preferably refracted at an interface between the waveguide and at least one adjacent medium of lower refractive index;
wherein the primary chromophore is embedded in the waveguide, is responsive to light within a first spectral band, and emits some light within a second spectral band,
wherein the auxiliary chromophore is responsive to light within a third spectral band, and emits at least some light within the first spectral band, and
wherein the primary chromophore and the auxiliary chromophore are physically separated by a sufficient distance for the auxiliary chromophore to luminesce.

2. The solar concentrator of claim 1, wherein the auxiliary chromophore is embedded in the waveguide.

3. The solar concentrator of claim 2, wherein the primary chromophore is spaced from the auxiliary chromophore by at least approximately 50 nanometers.

4. The solar concentrator of claim 3, wherein the auxiliary chromophore is disposed in a coating.

5. The solar concentrator of claim 1, wherein the auxiliary chromophore is disposed in or on a different structure than the structure in which the primary chromophore is disposed.

6. The solar concentrator of claim 1, wherein the primary chromophore transfers no resonant energy to any auxiliary chromophore.

7. The solar concentrator of claim 2, wherein the primary chromophore is disposed on the substrate, and wherein the auxiliary chromophore is disposed on a second substrate.

8. The solar concentrator of claim 2, wherein all light that is eventually redirected to the substrate passes through the primary chromophore.

9. The solar concentrator of claim 2, wherein the auxiliary chromophore is disposed in a highly scattering medium, and where the medium that contains the auxiliary chromophore is placed behind the medium that contains the primary chromophore.

10. The solar concentrator of claim 9, wherein the highly scattering medium is surrounded by mirrors on most sides of the highly scattering medium.

11. The solar concentrator of claim 1, where the auxiliary chromophores is contained in a medium, where the medium is surrounded by mirrors on most sides of the medium, where the medium that contains the auxiliary chromophore is placed behind the medium that contains the primary chromophore, and where the auxiliary chromophore is oriented such that it preferentially emits light towards the primary chromophore.
